(19) United States
(12) Patent Application Publication
(10) Pub. No.: US 2014/0116491 A1
(43) Pub. Date: May 1, 2014

(54) BULK-SIZE NANOSTRUCTURED MATERIALS AND METHODS FOR MAKING THE SAME BY SINTERING NANOWIRES

(71) Applicant: Alphabet Energy, Inc., Hayward, CA (US)

(72) Inventors: John Reifenberg, Pleasanton, CA (US); Saniya LeBlanc, San Francisco, CA (US); Matthew L. Scullin, San Francisco, CA (US)

(73) Assignee: Alphabet Energy, Inc., Hayward, CA (US)

(21) Appl. No.: 14/062,803

(22) Filed: Oct. 24, 2013

Related U.S. Application Data
(60) Provisional application No. 61/719,639, filed on Oct. 29, 2012.
(60) Provisional application No. 61/801,611, filed on Mar. 15, 2013.

(51) Int. Cl. H01L 35/22; C01B 33/02; H01L 35/34; H01L 35/12

(52) U.S. Cl. CPC H01L 35/22; H01L 35/12; C01B 33/02; H01L 35/34
USPC 136/203; 136/200; 136/205; 423/348; 252/500; 216/13; 427/58; 136/201

(57) ABSTRACT

Thermoelectric solid material and method thereof. The thermoelectric solid material includes a plurality of nanowires. Each nanowire of the plurality of nanowires corresponds to an aspect ratio (e.g., a ratio of a length of a nanowire to a diameter of the nanowire) equal to or larger than 10, and each nanowire of the plurality of nanowires is chemically bonded to one or more other nanowires at at least two locations of the each nanowire.

### 1. CROSS-REFERENCES TO RELATED APPLICATIONS

This application claims priority to U.S. Provisional Application No. 61/719,639, filed Oct. 29, 2012, and U.S. Provisional Application No. 61/801,611, filed Mar. 15, 2013, commonly assigned and incorporated by reference herein for all purposes.

Additionally, this application is related to U.S. patent application Ser. Nos. 13/299,179 and 13/308,945, which are incorporated by reference herein for all purposes.

### 2. BACKGROUND OF THE INVENTION

The present invention is directed to nanostructured materials. More particularly, the invention provides bulk-size nanostructured solid materials by sintering nanowires according to certain embodiments. Merely by way of example, the invention has been applied to making thermoelectric devices. However, it would be recognized that the invention has a much broader range of applicability.

Nanostructured semiconductor materials have been shown to have good thermoelectric figures of merit ZT for making high performance thermoelectric devices. For example, silicon nanowires, nanoholes, and nanomesh have been formed and result in materials with nano-size features. Some of these conventional structures are nanowires with aspect ratios of length to diameter greater than ten-to-one. For example, the nanowires have been shown to have lower thermal conductivity and therefore higher thermoelectric figure-of-merit ZT than bulk single crystals or polycrystals of the same material. In another example, the nanowires have diameters that range from 1 to 250 nm. In yet another example, the nanowires have roughened or porous features that range in size from 1 to 100 nm. Similarly, some of these conventional structures are thin films that resemble ribbons. For example, the ribbons have been shown to be less than ten microns wide and less than ten microns long, tens to hundreds of nanometers thick, with holes within the ribbons. In another example, the holes have diameters that range from 1 nm to 100 nm. These conventional structures demonstrate the fundamental ability of nanostructures to affect phonon thermal transport by reducing thermal conductivity while not affecting electrical properties greatly, thereby improving the thermoelectric figure-of-merit ZT, given by ZT=S²σ/k, where S is the materials' thermopower, σ is the electrical conductivity, and k is the thermal conductivity. However, the nano-size features in these nanostructured materials often limit the materials' applicability in transporting significant amounts of current from one electrode to another in the case of power generation, where a temperature gradient is applied to the thermoelectric materials and the Seebeck effect is employed to drive a gradient in voltage and in turn the flow of electrical current. For example, a small collection of nanowires would not provide enough material volume to transport enough energy to be used in practical applications. In another example, the use of nanowires or thin-film nanoribbons less than 100 μm in length would create limitations in the ability to maintain an appreciable temperature gradient across these nanowires or nanoribbons using conventional heat exchanger technology. Conversely, these conventional nanostructured materials with nano-size features also impose limits on the materials for carrying an appreciable amount of heat with an applied electric current by way of the Peltier effect.

FIG. 1A is a simplified diagram showing different types of nano-scale structures and/or micro-scale structures being mixed to form a randomly or partially ordered mixture through a spark plasma sintering process. As shown in FIG. 1A, nano-scale or micro-scale structures 1410 of one type (e.g., nanoparticles or nanowires of one type) and nano-scale or micro-scale structures 1420 of another type (e.g., nanoparticles or nanowires of another type) are mixed to form a randomly or partially ordered mixture through a spark plasma sintering process. For example, the randomly or partially ordered mixture of micro-scale and/or nano-scale particles and/or other micro-scale and/or nano-scale materials can provide a benefit of preventing a formation of any larger-size grain in the volume of the sintered product. In another example, the randomly or partially ordered mixture is used to inhibit grain growth of the thermoelectric material during sintering of a nanostructure powder (e.g., a silicon nanowire powder) in order to reduce the thermal conductivity of the formed bulk-size nanostructured material.

FIG. 1B is a simplified diagram showing different types of nano-scale or micro-scale particles being mixed to form an interactive mixture through a spark plasma sintering process. As shown in FIG. 1B, nano-scale or micro-scale structures 1430 of one type (e.g., nanoparticles or nanowires of one type) and nano-scale or micro-scale structures 1440 of another type (e.g., nanoparticles or nanowires of another type) are mixed to form an interactive mixture through a spark plasma sintering process. For example, the interactive mixture of micro-scale and/or nano-scale particles and/or other micro-scale and/or nano-scale materials can provide a benefit of preventing a formation of any larger-size grain in the volume of the sintered product. In another example, the inactive mixture is used to inhibit grain growth of the thermoelectric material during sintering of a nanostructure powder (e.g., a silicon nanowire powder) in order to reduce the thermal conductivity of the formed bulk-size nanostructured material.

Hence, it is highly desirable to create bulk materials that can transport significant amounts of heat and electric current with improved transportation efficiency.

### 3. BRIEF SUMMARY OF THE INVENTION

The present invention is directed to nanostructured materials. More particularly, the invention provides bulk-size nanostructured solid materials by sintering nanowires according to certain embodiments. Merely by way of example, the invention has been applied to making thermoelectric devices. However, it would be recognized that the invention has a much broader range of applicability.

According to one embodiment, a thermoelectric solid material includes a plurality of nanowires. Each nanowire of the plurality of nanowires corresponds to an aspect ratio (e.g., a ratio of a length of a nanowire to a diameter of the nanowire) equal to or larger than 10, and each nanowire of the plurality of nanowires is chemically bonded to one or more other nanowires at at least two locations of the each nanowire.

According to another embodiment, a thermoelectric solid material includes a multiply connected structure including a plurality of structural components and a plurality of connection components. The plurality of structural components are connected by the plurality of connection components. The plurality of structural components and the plurality of connection components include one or more first materials, each connection component of the plurality of connection components corresponds to an aspect ratio (e.g., a ratio of a length of a connection component to a width of the connection component) equal to or larger than 10, each connection component of the plurality of connection components is separated from a structural component or another connection component by one or more voids, and the one or more voids correspond to a thermal conductivity less than 5 W/m-K. The thermoelectric solid material is associated with a first volume, the plurality of structural components and the plurality of connection components are associated with a second volume, and a ratio of the second volume to the first volume ranges from 20% to 99.9%. The thermoelectric solid material is associated with a thermoelectric figure of merit ZT larger than 0.1.

According to yet another embodiment, a thermoelectric solid material includes a plurality of silicon grains. Each grain of the plurality of silicon grains is smaller than 250 nm in any dimension, and each grain of the plurality of silicon grains corresponds to an aspect ratio (e.g., a ratio of a length of a silicon grain to a width of the silicon grain) equal to or larger than 10.

According to yet another embodiment, a thermoelectric solid material includes a plurality of nanostructures. The thermoelectric solid material is associated with a Hausdorff dimension larger than zero and smaller than three, and the thermoelectric solid material is associated with a thermoelectric figure of merit ZT larger than 0.1.

According to yet another embodiment, a method for making a thermoelectric solid material includes providing a plurality of nanowires. Each nanowire of the plurality of nanowires is in contact with at least another nanowire of the plurality of nanowires. Additionally, the method includes sintering the plurality of nanowires under a temperature higher than 25° C. or under a pressure higher than 760 torr to form the thermoelectric solid material.

According to yet another embodiment, a thermoelectric solid material made by a process. The process includes providing a plurality of nanowires, each nanowire of the plurality of nanowires being in contact with at least another nanowire of the plurality of nanowires, and sintering the plurality of nanowires under a temperature higher than 25° C. or under a pressure higher than 760 torr to form the thermoelectric solid material.

Depending upon the embodiment, one or more benefits may be achieved. These benefits and various additional objects, features, and advantages of the present invention can be fully appreciated with reference to the detailed description and accompanying drawings that follow.

### 4. BRIEF DESCRIPTION OF THE DRAWINGS

FIG. 1A is a simplified diagram showing different types of nano-scale structures and/or micro-scale structures being mixed to form a randomly or partially ordered mixture through a spark plasma sintering process.

FIG. 1B is a simplified diagram showing different types of nano-scale or micro-scale particles being mixed to form an interactive mixture through a spark plasma sintering process.

FIGS. 2A and 2B are SEM images showing sintered nanowires according to certain embodiments of the present invention.

FIG. 3A is a simplified diagram showing a side view of a bulk-size nanostructured material formed by sintering nanowires according to one embodiment of the present invention.

FIG. 3B is a simplified diagram showing a bulk-size nanostructured pellet formed by sintering nanowires according to another embodiment of the present invention.

FIG. 4 is a simplified diagram showing a side view of a bulk-size solid material including one or more bulk-size layers formed by sintering nanowires according to one embodiment of the present invention.

FIGS. 5A and 5B are simplified diagrams showing a top-view cross-section and a side-view cross-section of a bulk-size solid material including one or more shells and one or more cores formed by sintering nanowires according to one embodiment of the present invention.

FIG. 6A is a simplified diagram showing a bulk-size composite material by sintering one or more mixtures of one or more silicon nanowire powders and one or more fill materials according to one embodiment of the present invention, and FIG. 6B is a simplified diagram showing another bulk-size composite material by sintering one or more mixtures of one or more silicon nanowire powders and one or more fill materials according to another embodiment of the present invention.

FIG. 7 is a simplified diagram showing a method for fabricating bulk-size nanostructured thermoelectric legs according to an embodiment of the present invention.

FIG. 8 is a simplified diagram showing a method for fabricating bulk-size nanostructured thermoelectric legs according to another embodiment of the present invention.

FIG. 9 is a simplified diagram showing a method for fabricating bulk-size nanostructured thermoelectric legs according to yet another embodiment of the present invention.

FIG. 10 is a simplified diagram showing a method for fabricating bulk-size nanostructured thermoelectric legs according to yet another embodiment of the present invention.

FIG. 11 is a simplified diagram showing a method for fabricating bulk-size nanostructured thermoelectric legs according to yet another embodiment of the present invention.

FIG. 12A is a simplified diagram showing a plurality of nanowires being partially aligned in a plane perpendicular to a direction of a sintering pressure applied during a sintering process according to one embodiment of the present invention.

FIG. 12B is a simplified diagram showing a plurality of nanowires being aligned along a common direction by an electric current and a magnetic field applied during a sintering process according to another embodiment of the present invention.

FIG. 12C is a simplified diagram showing a plurality of nanowires being substantially aligned by a chemical repelling mechanism during a sintering process according to yet another embodiment of the present invention.

FIG. 13 is a simplified diagram showing measurement results for two samples of bulk-size nanostructured materials formed by sintering of one or more nanowire powders according to certain embodiments of the present invention.

FIG. 14 is a simplified diagram showing thermoelectric measurement results for a bulk-size nanostructured material formed by sintering one or more nanowire powders according to some embodiments of the present invention.

FIG. 15 is a simplified SEM image showing spontaneous formation of one or more controlled-size nano-scale and/or micro-scale lamellae of varying chemical compositions according to an embodiment of the present invention.

FIGS. 16A-F are simplified diagrams showing various configurations of nanowires, nanofibers, nanoparticles, and/or grains thereof in an interconnected structure fanned between electrodes according certain embodiments of the present invention.

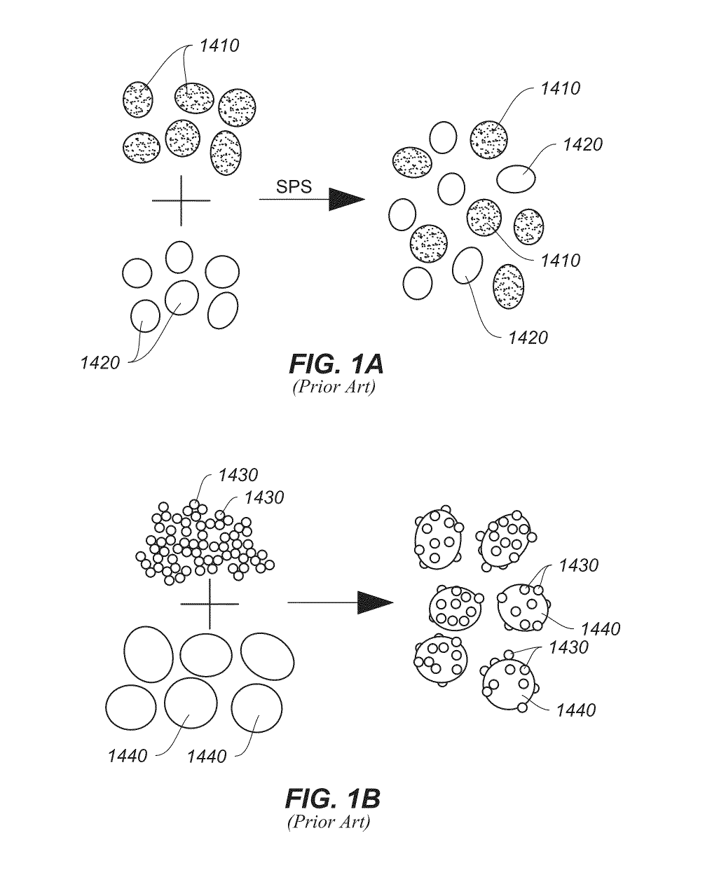

### 5. DETAILED DESCRIPTION OF THE INVENTION

The present invention is directed to nanostructured materials. More particularly, the invention provides bulk-size nanostructured solid materials by sintering nanowires according to certain embodiments. Merely by way of example, the invention has been applied to making thermoelectric devices. However, it would be recognized that the invention has a much broader range of applicability.

In order to become applicable to macro-scale applications such as waste-heat recovery, nanostructured thermoelectric materials with sub-ten-micron features need to be made into bulk-size nanostructured materials, such as bulk-size solid materials with nano-sized features used for making electronic devices for various applications according to some embodiments. For example, a bulk-sized nanostructured material may be a nano-composite material. In another example, the bulk-size nanostructured materials have desirable thermoelectric, thermal, electrical, mechanical, and/or corrosion properties. In another example, these electronic devices include power generators, solid state coolers, and/or other electronic devices.

According to some embodiments, it is highly desirable to create bulk materials that can transport significant amounts of heat and electric current but have nano-scale and/or sub-ten-micron features to enhance the efficiency of the bulk materials in transportation of heat and electrical current.

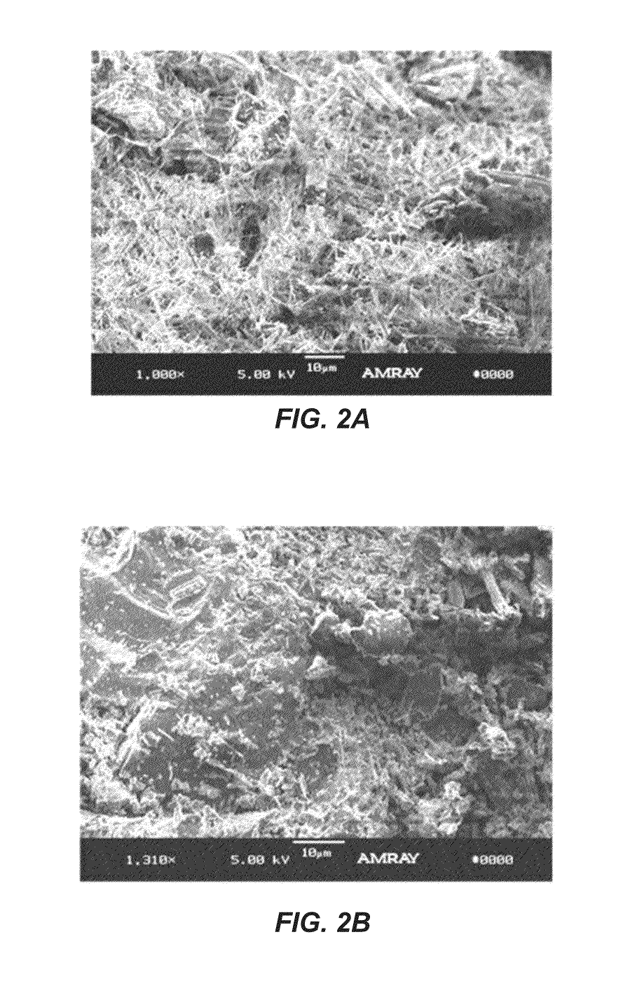

FIGS. 2A and 2B are SEM images showing sintered nanowires according to certain embodiments of the present invention. These diagrams are merely examples, which should not unduly limit the scope of the claims. One of ordinary skill in the art would recognize many variations, alternatives, and modifications.

In one embodiment, silicon nanowires are prefabricated by directly etching into a single-crystal silicon wafer. For example, the silicon wafer is pre-doped so as to make the fabricated silicon nanowires also doped accordingly. In another example, after formation of the arrays of silicon nanowires from the silicon wafer, these silicon nanowires are scratched from the remaining wafer structure and collected in a powder form. In another embodiment, a sintering process is applied to transform one or more powders of silicon nanowires into a bulk-size composite material.

As shown in FIGS. 2A and 2B, a nanostructured silicon powder (e.g., silicon nanowires in a powder form) is sintered together with its internal nanostructure features at least partially retained. For example, before sintering, the powder material includes some nanowires aligned, some nanowires unaligned, and/or some nanowires randomly tangled. In another example, before sintering, the powder material includes some nanowires having roughened surfaces and/or some nanowires not having roughened surfaces. According to one embodiment, the sintering process leads to a fusing effect in micro-scale at edge-contact regions and/or crossing-contact regions between nanowires within the powder material to cause a formation of interconnected nanowires throughout the volume of the formed bulk-size composite material. According to another embodiment, by the sintering process, the nanostructured powder material can be turned into various shapes in bulk sizes.

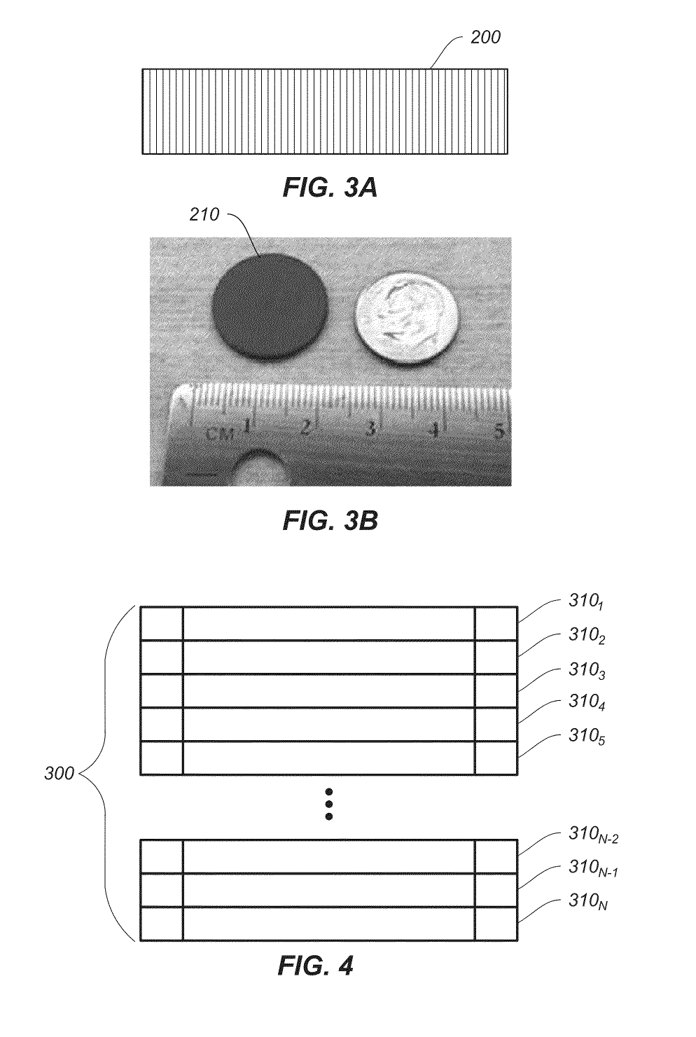

FIG. 3A is a simplified diagram showing a side view of a bulk-size nanostructured material formed by sintering nanowires according to one embodiment of the present invention. This diagram is merely an example, which should not unduly limit the scope of the claims. One of ordinary skill in the art would recognize many variations, alternatives, and modifications.

As shown in FIG. 3A, a silicon nanowire powder is sintered into a sheet of bulk-size material 200 with a disk shape. In another embodiment, the silicon nanowire powder is sintered to form a bulk-size material with a curved top surface and/or a curved bottom surface.

For example, the bulk-size material 200 includes interconnected nanostructures (e.g., interconnected nanowires) within the material 200. In another example, the bulk-size material 200 can be in various shapes with varying cross-section areas, including nanostructures at least partially retained within the material 200.

FIG. 3B is a simplified diagram showing a bulk-size nanostructured pellet formed by sintering nanowires according to another embodiment of the present invention. This diagram is merely an example, which should not unduly limit the scope of the claims. One of ordinary skill in the art would recognize many variations, alternatives, and modifications. For example, the bulk-size nanostructured pellet 210 is the bulk-size nanostructured material 210.

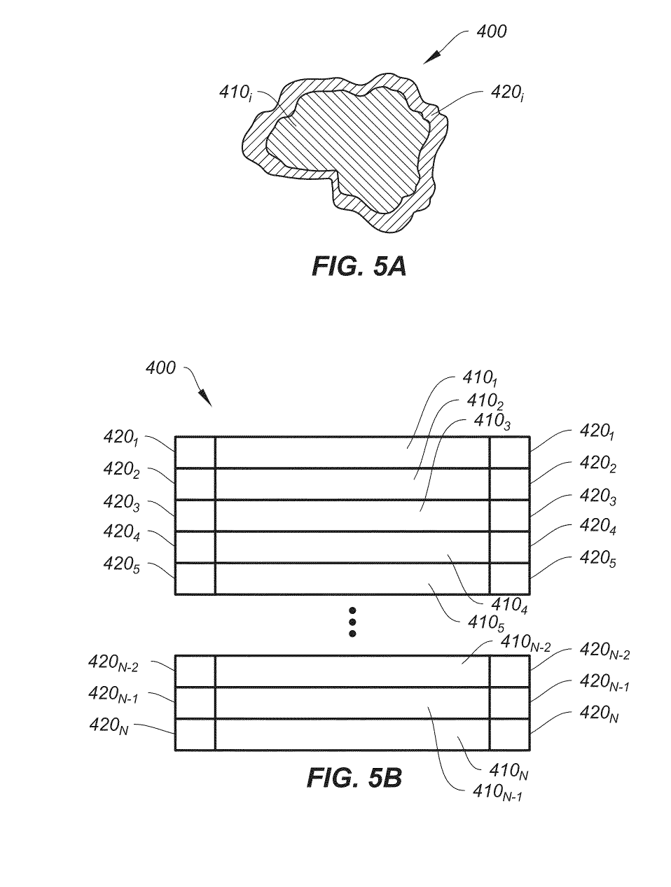

FIG. 4 is a simplified diagram showing a side view of a bulk-size solid material including one or more bulk-size layers formed by sintering nanowires according to one embodiment of the present invention. This diagram is merely an example, which should not unduly limit the scope of the claims. One of ordinary skill in the art would recognize many variations, alternatives, and modifications.

As shown in FIG. 4, the bulk-size solid material 300 includes one or more bulk-size layers. For example, the bulk-size layers are arranged in a functionally graded manner. In one embodiment, powders of multiple types of materials separately undergo one or more sintering processes to form, respectively, multiple pellets (e.g., multiple pellets 210), and then these multiple pellets are sintered together, with or without one or more other pellets, to form the bulk-size solid material 300. For example, one or more adhesive materials are deposited between these multiple pellets before these pellets are sintered together. In another embodiment, powders of multiple types of materials are deposited respectively layer by layer, then these multi-layered powders are sintered together to form the bulk-size solid material 300.

According to one embodiment, for the bulk-size solid material 300, each of the bulk-size layers is chosen and/or tuned in terms of the layer's thickness, mechanical, thermal, electrical, thermoelectric, and/or corrosion properties depending on specific application of the bulk-size solid material 300. For example, to improve the thermoelectric performance of the bulk-size solid material 300, some of the powders of multiple types of materials are made from silicon nanowires with different doping characteristics and/or different types of low-thermal conductivity fill materials, respectively. In another example, over and/or under these silicon nanowires powders, one or more conductive materials are used to enhance thermal contact and/or electrical conduction. In yet another example, additional top and/or bottom layers include one or more corrosion resistant materials and/or one or more high-temperature accessible materials.

According to another embodiment, the bulk-size solid material 300 includes the bulk-size layers 310₁, 310₂, 310₃, 310₄, 310₅, . . . , 310_{N-2}, 310_{N-1}, and 310_{N}, wherein N is larger than or equal to 1. For example, the bulk-size layer 310₁ includes a high-temperature corrosion-resistant metal with good brazing properties, the bulk-size layer 310₂ includes a metal that makes good electrical contacts to the bulk-size layers 310₁ and 310₃, and the bulk-size layer 310₃ includes a thermoelectric material chosen for high temperatures. In another example, the bulk-size layer 310₄ includes a thermoelectric material chosen for mid-temperatures, and/or the bulk-size layer 310₄ includes an electrical contact material between the bulk-size layers 310₃ and 310₅. In yet another example, the bulk-size layer 310_{N-2} includes a thermoelectric material chosen for low temperatures, the bulk-size layer 310_{N-1} includes a contact metal, and the bulk-size layer 310_{N} includes a bonding metal.

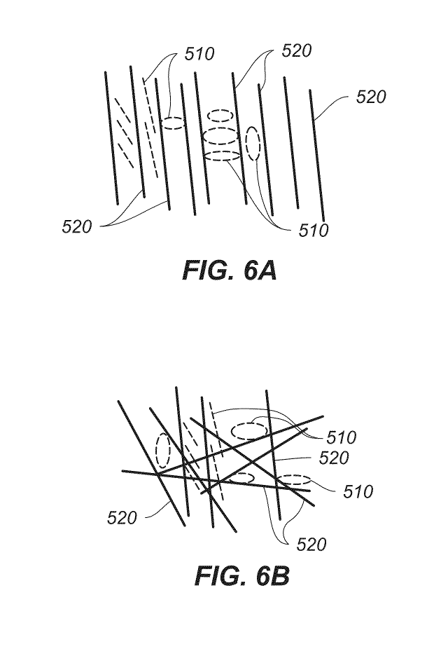

FIGS. 5A and 5B are simplified diagrams showing a top-view cross-section and a side-view cross-section of a bulk-size solid material including one or more shells and one or more cores formed by sintering nanowires according to one embodiment of the present invention. These diagrams are merely examples, which should not unduly limit the scope of the claims. One of ordinary skill in the art would recognize many variations, alternatives, and modifications.

According to one embodiment, the bulk-size solid material 400 includes the bulk-size core layers 410₁, 410₂, 410₃, 410₄, 410₅, . . . , 410_{N-2}, 410_{N-1}, and 410_{N}, and the shell layers 420₁, 420₂, 420₃, 420₄, 420₅, . . . , 420_{N-2}, 420_{N-1}, and 420_{N}, wherein N is larger than or equal to 1. For example, the bulk-size core layers 410₁, 410₂, 410₃, 410₄, 410₅, . . . , 410_{N-2}, 410_{N-1}, and 410_{N} are the same as the bulk-size layers 310₁, 310₂, 310₃, 310₄, 310₅, . . . , 310_{N-2}, 310_{N-1}, and 310_{N}, respectively. In another example, the shell layer 420ᵢ surrounds the corresponding core layer 410ᵢ, where 1≦i≦N.

According to another embodiment, the methods for making the bulk-size solid material 400 possess flexibility for many multi-layer engineering of different materials before depositing desirable types of powder materials in predetermined layers with predetermined shapes and/or forms, respectively. For example, at least some of the bulk-size core layers 410₁, 410₂, 410₃, 410₄, 410₅, . . . , 410_{N-2}, 410_{N-1}, and 410_{N} include multiple materials (e.g., functionally graded thermoelectric materials) to improve thermoelectric, thermal, electrical, mechanical, chemical, corrosion, and/or manufacturability properties of the composite material 400. In another example, the combination of a core layer 410ᵢ and its surrounding shell layer 420ᵢ can have various shapes.

As shown in FIG. 5A, a core layer 410ᵢ of a thermoelectric material is surrounded by a corresponding shell layer 420ᵢ of an electrical and thermal insulating material on the sides. As shown in FIG. 5B, the bulk-size core layers 410₁, 410₂, 410₃, 410₄, 410₅, . . . , 410_{N-2}, 410_{N-1}, and 410_{N} are functionally graded, and the shell layers 420₁, 420₂, 420₃, 420₄, 420₅, . . . , 420_{N-2}, 420_{N-1}, and 420_{N} are also functionally graded. For example, some of the bulk-size core layers 410₁, 410₂, 410₃, 410₄, 410₅, . . . , 410_{N-2}, 410_{N-1}, and 410_{N} do not include any nanostructured material. In another example, some or all of the shell layers 420₁, 420₂, 420₃, 420₄, 420₅, . . . , 420_{N-2}, 420_{N-1}, and 420_{N} do not include any nanostructured material.

As discussed above and further emphasized here, FIGS. 5A and 5B are merely examples, which should not unduly limit the scope of the claims. One of ordinary skill in the art would recognize many variations, alternatives, and modifications. For example, two or more of the shell layers 420₁, 420₂, 420₃, 420₄, 420₅, . . . , 420_{N-2}, 420_{N-1}, and 420_{N} have the same composition and are combined into one layer that surrounds two or more corresponding bulk-size core layers. In another example, the shell layer 420ᵢ has the same thickness or different thickness in comparison with the corresponding core layer 410ᵢ.

In one embodiment, a bulk-size composite material is provided by sintering one or more mixtures of one or more nanostructured powders (e.g., one or more silicon nanowire powders) and one or more fill materials. For example, before the sintering process, the one or more nanostructured powders are mixed with the one or more fill materials. In another example, the one or more fill materials are selected from air, oxide, ceramic, and/or other materials. In yet another example, the one or more fill materials do not need to be pre-processed into a powdered form. In another embodiment, by sintering the one or more mixtures, the thermoelectric, thermal, electrical, mechanical, chemical, corrosion, and/or manufacturability properties of the bulk-size material can be specifically improved.

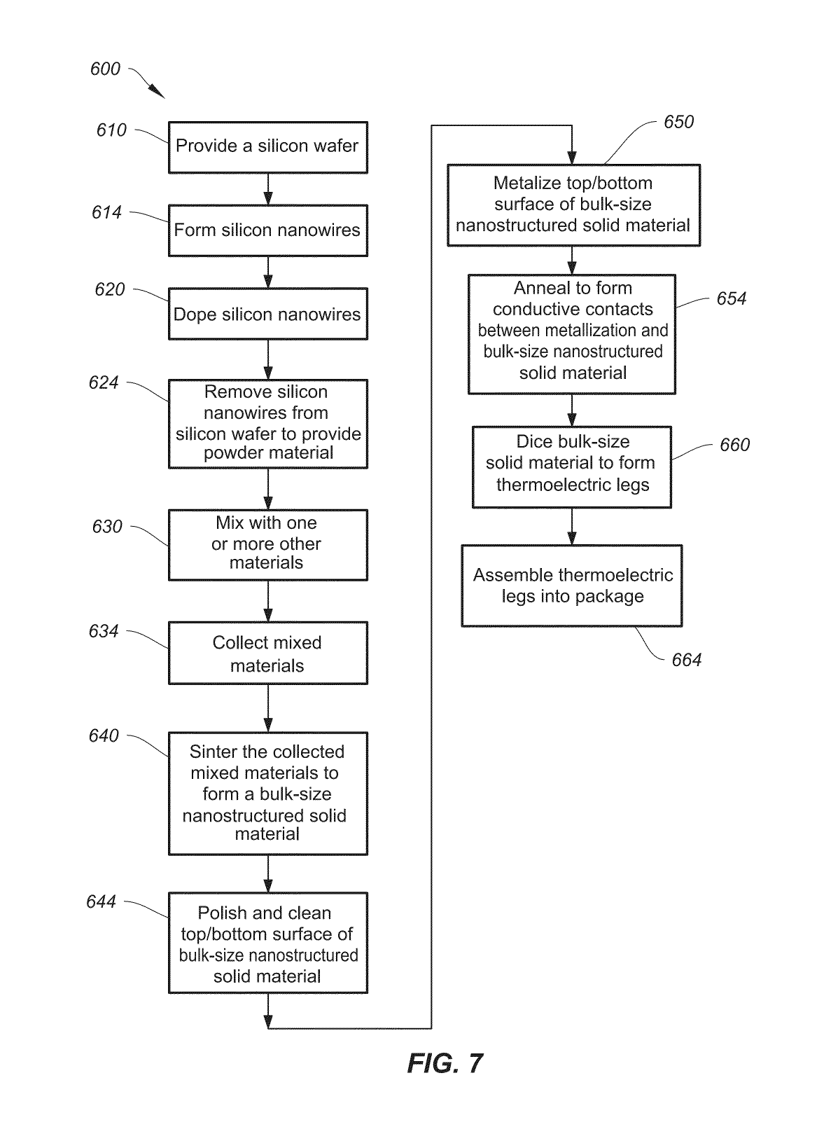

FIG. 6A is a simplified diagram showing a bulk-size composite material by sintering one or more mixtures of one or more silicon nanowire powders and one or more fill materials according to one embodiment of the present invention, and FIG. 6B is a simplified diagram showing another bulk-size composite material by sintering one or more mixtures of one or more silicon nanowire powders and one or more fill materials according to another embodiment of the present invention. These diagrams are merely examples, which should not unduly limit the scope of the claims. One of ordinary skill in the art would recognize many variations, alternatives, and modifications.

In one embodiment, the one or more silicon nanowire powders include active nanostructured thermoelectric materials, and the one or more fill materials are either nanostructure or not nanostructured to occupy the interstitial volume between the nanostructured thermoelectric materials. For example, the one or more fill materials are chemically active to react with one or more surface materials on surfaces of nanostructured thermoelectric materials (e.g., react with silicon dioxide on surfaces of silicon nanowires). In another example, the one or more fill materials are chemically inert. In another embodiment, the one or more fill materials are supplied in a variety of shapes such as wires, spheres, ellipsoids, and/or cubes. In yet another embodiment, the one or more fill materials can partially or fully react or diffuse into the body of the nanostructured thermoelectric materials (e.g., the body of the silicon nanowires) during sintering to produce enhanced thermoelectric properties.

As shown in FIGS. 6A and 6B, the bulk-size composite material 500 formed by sintering one or more mixtures of one or more silicon nanowire powders and one or more fill materials has a solid shape in macro scale. For example, within the bulk-size composite material 500, one or more fill materials 510 (e.g., reactive fill material, inert fill material) fill in the interstitial regions between one or more silicon nanowires 520. In another example, the one or more fill materials 510 are used to modify and/or enhance electrical, chemical, mechanical, and/or thermal properties of the one or more silicon nanowires 520.

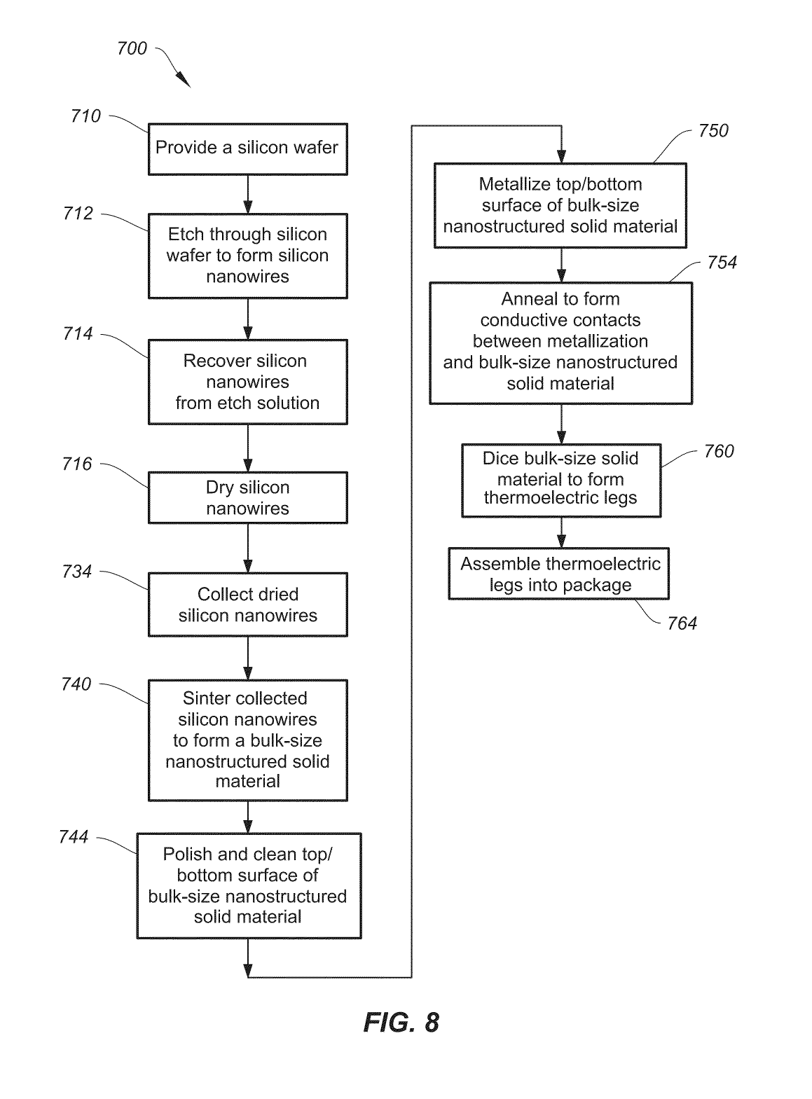

FIG. 7 is a simplified diagram showing a method for fabricating bulk-size nanostructured thermoelectric legs according to an embodiment of the present invention. This diagram is merely an example, which should not unduly limit the scope of the claims. One of ordinary skill in the art would recognize many variations, alternatives, and modifications. As shown in FIG. 7, the method 600 includes processes 610, 614, 620, 624, 630, 634, 640, 644, 650, 654, 660, and 664. Although the above has been shown using a selected group of processes for the method 600, there can be many alternatives, modifications, and variations. For example, some of the processes may be expanded and/or combined. Other processes may be inserted to those noted above. In another example, some of the processes may be replaced, removed, re-arranged, overlapped, and/or partially overlapped. Further details of these processes are found throughout the present specification and more particularly below.

At the process 610, a silicon wafer is provided. For example, the silicon wafer is undoped. In another example, the silicon wafer is doped (e.g., lightly doped or heavily doped) in either p-type or n-type characteristics for different embodiments. At the process 614, silicon nanowires are formed. In one embodiment, the silicon wafer is subjected to an etching process to produce a plurality of nanowires through at least a partial thickness of the silicon wafer. In another embodiment, the silicon nanowires are formed with or without rough walls. For example, the rough walls can cause low thermal conductivity.

At the process 620, the silicon nanowires are doped. In one embodiment, the doping process is applied to produce desired electrical and thermoelectric properties. In another embodiment, the doping of the silicon nanowires is accomplished through a filling process. For example, impurity dopants are added through an injection of one or more fill materials into the interstitial regions of the as-formed silicon nanowires. In yet another embodiment, dopants are mixed with one or more fill materials in a gaseous form to fill the voids between the nanowires and reactively diffuse into the nanowires. At the process 624, the silicon nanowires are removed from the remaining portion of the silicon wafer to provide a silicon nanowire powder. For example, the removed silicon nanowires take a form of powders or clusters.

At the process 630, the silicon nanowire powder is mixed with one or more additional materials. For example, the one or more additional materials are used to modify one or more properties of the nanowires within the silicon nanowire powder. In another example, the one or more additional materials include one or more dopants, one or more low-thermal-conductivity fill materials, one or more other chemical-reactive materials, and/or one or more other chemical-inert materials. In yet another example, the one or more additional materials are in the powder form and supplied in small particles with a variety of shapes such as wires, spheres, ellipsoids, and/or cubes. At the process 634, the mixed materials including the silicon nanowire powder and the one or more additional materials are collected into a holder (e.g., a graphite holder with a predetermined shape and/or a predetermined size).

At the process 640, the collected mixed materials are sintered to form a bulk-size nanostructured solid material. In one embodiment, the formed bulk-size nanostructured solid material is the same as the sheet of bulk-size material 200, the bulk-size nanostructured pellet 210, the bulk-size solid material 300, and the bulk-size solid material 400. In another embodiment, the sintering process is carried under certain conditions of temperature, pressure, time, temperature ramping speed, and/or pressure ramping speed, assisted by spark plasma and/or electrical current, in a sealed chamber. In yet another embodiment, after the sintering process, the formed bulk-size nanostructured solid material is selectively inspected by microscope about its internal structure and evaluated by measuring its thermoelectric power density. For example, the sintering process can produce a bulk-size nanostructured solid material that is a wafer or disk with desired shape, lateral dimension, thickness, and/or density. In another example, the produced bulk-size nanostructured solid material includes interconnected nanostructures and bears a thermoelectric power density substantially higher than a bulk-size non-nanostructure solid material. At the process 644, the formed bulk-size nanostructured solid material is polished and cleaned. For example, the polishing process is performed to obtain a desired final thickness and/or a desired surface smoothness. In another example, the polishing process is followed by a cleaning process to prepare the top surface and/or the bottom surface of the bulk-size nanostructured solid material.

At the process 650, the top surface and/or the bottom surface of the bulk-size nanostructured solid material is metalized. In one embodiment, the metallization process is performed to deposit one or more metal materials (e.g., a conductive contact layer) on the top surface and/or the bottom surface of the bulk-size nanostructured solid material. For example, the top surface of the bulk-size nanostructured solid material is configured to serve as a hot-side contact, and the bottom surface of the bulk-size nanostructured solid material is configured to serve as a cold-side contact. In another example, the metal deposition is performed by sputtering, evaporation, plating, and/or electroless deposition. In another embodiment, different materials are used for depositing and forming the conductive contact layer on the top surface and the conductive layer on the bottom surface in order to be adaptive to different temperature environments for the top surface and the bottom surface. At the process 654, the bulk-size nanostructured solid material with the metalized top surface and/or the metalized bottom surface is annealed for thermal treatment. For example, the anneal process is performed to form good electrical contact between the metallization (e.g., one or more deposited metal materials) and the bulk-size nanostructured solid material. In another example, the anneal process leads to a formation of conductive contacts on both the top and bottom surfaces of the bulk-size nanostructured solid material with interconnected nanostructures.

At the process 660, the bulk-size nanostructured solid material with a conductive contact layer on the top surface and/or a conductive contact layer on the bottom surface is diced into individual units each with a desired size. In one embodiment, the lateral size of each unit is comparable with its thickness. In another embodiment, each unit retains the structure of the bulk-size nanostructured solid material with a conductive contact layer on the top surface and/or a conductive contact layer on the bottom surface. In yet another embodiment, each unit is directly used as a thermoelectric leg. For example, each thermoelectric leg is an n-type leg or a p-type leg, depending on doping characteristics of the silicon wafer provided at the process 610, doping of the nanowires at the process 620, and/or any doping modification performed during or after the process 630, 634, and/or 640. At the process 664, a thermoelectric module is assembled by arranging n-type legs and p-type legs in a multi-leg package. For example, the n-type legs and the p-type legs are arranged in a designated order. In another example, the n-type legs and the p-type legs have common or separated electrical/thermal contacts.

As discussed above and further emphasized here, FIG. 7 is merely an example, which should not unduly limit the scope of the claims. One of ordinary skill in the art would recognize many variations, alternatives, and modifications. In one embodiment, the method 600 is modified to make thermoelectric legs by sintering nanowires of materials other than silicon. In another embodiment, the method 600 is modified to make thermoelectric legs by sintering nanostructures other than nanowires. For example, at the process 614, the etching process is modified to produce one or more nanoporous structures, one or more nanodisc structures, one or more nanocones, one or more nanospheres, one or more nanocubes, and/or other one or more nanostructures with desired thermoelectric properties. In another example, at the process 614, the formation of nanowires, one or more nanoporous structures, one or more nanodisc structures, one or more nanocones, one or more nanospheres, one or more nanocubes, and/or other one or more nanostructures is accomplished by one or more growth techniques, including crystal growth, thin film deposition, chemical reactive growth, atomic layer deposition, and/or other techniques.

In yet another embodiment, the process 620 is skipped. For example, the doping process 620 is skipped if the original silicon wafer provided at the process 610 has been properly doped. In another example, the doping process 620 is replaced by the doping modification performed during or after the process 630, 634, and/or 640. In yet another embodiment, the process 630 is skipped. For example, the process 630 is skipped, so that at the process 634, the silicon nanowire powder is collected into a holder (e.g., a graphite holder) that has a predetermined shape and/or a predetermined size, and at the process 640, the collected material is sintered to form a bulk-size nanostructured solid material.

In yet another embodiment, the process 650 is modified or replaced by another process. For example, a metal film is directly sintered onto the top surface and/or the bottom surface of the bulk-size nanostructured solid material. In another example, before the sintering process at the process 640, one or more metal powders are selectively deposited above or below the mixed materials that include the silicon nanowire powder and the one or more additional materials, so that the metallization on the top surface and the bottom surface of the bulk-size nanostructured solid material is accomplished metalized during the sintering process. In yet another example, one or more metal powders are pre-sintered together to form one or more metal pellets and/or one or more metal wafers. Afterwards, these one or more metal pellets and/or one or more metal wafers are selectively deposited above or below the bulk-size nanostructured solid material that has been formed by a sintering process, and then yet another sintering process is performed to bond these one or more metal pellets and/or one or more metal wafers together with the bulk-size nanostructured solid material, so that the bulk-size nanostructured solid material has at least one contact layer attached to its top surface and at least one contact layer attached to its bottom surface.

In yet another embodiment, during the process 640, the bulk-size nanostructured solid material is formed with any exotic shapes that can be implemented for making the thermoelectric legs with one or more contact surfaces adaptive to one or more specially-shaped thermal sources. For example, one or more shaped metallization layers (e.g., one or more contact layers) are formed in situ in the sintering process of the process 640 to form one or more good contacts directly with the corresponding shaped top and/or bottom surfaces of the bulk-size nanostructured solid material. In yet another embodiment, at the process 644, the polishing and cleaning processes are performed to retain the shape of the bulk-size nanostructured solid material that has been formed at the process 640, while providing a clean top surface and/or a clean bottom surface for bonding corresponding contact layers to the specially-shaped top and/or bottom surfaces. In yet another embodiment, the process 654 is skipped.

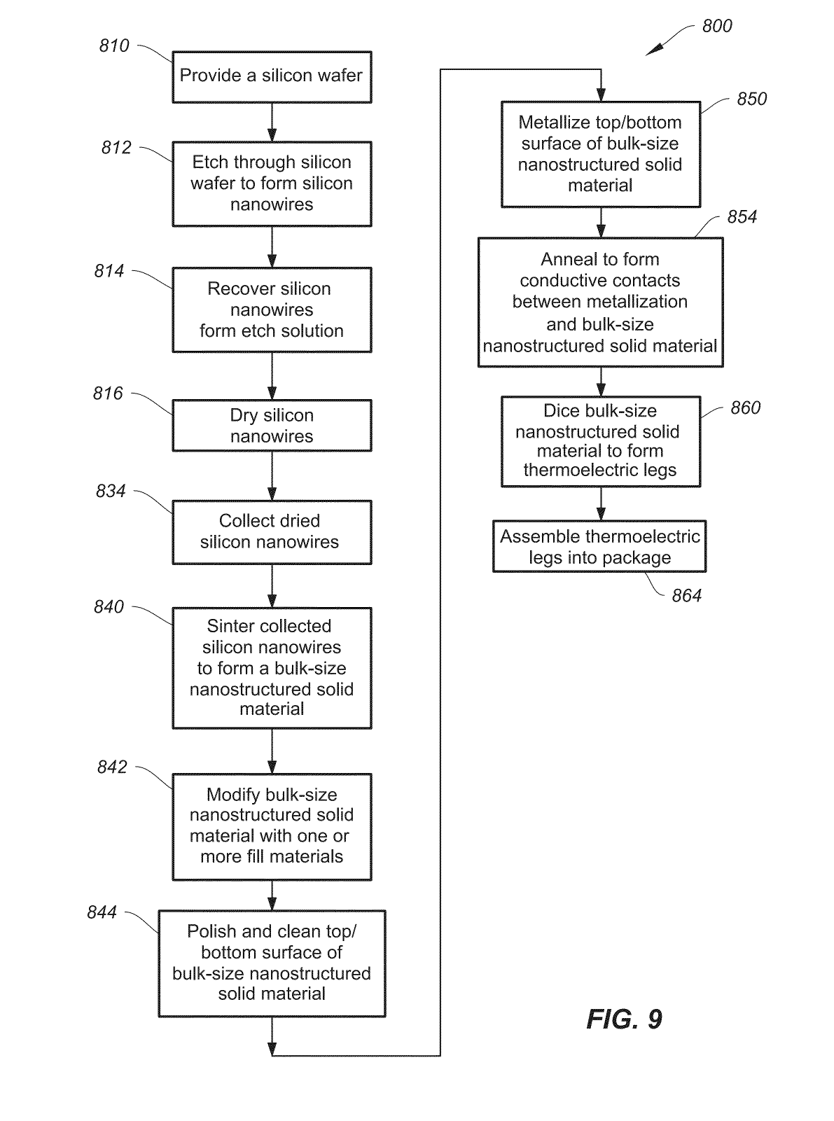

FIG. 8 is a simplified diagram showing a method for fabricating bulk-size nanostructured thermoelectric legs according to another embodiment of the present invention. This diagram is merely an example, which should not unduly limit the scope of the claims. One of ordinary skill in the art would recognize many variations, alternatives, and modifications. As shown in FIG. 8, the method 700 includes processes 710, 712, 714, 716, 734, 740, 744, 750, 754, 760, and 764. Although the above has been shown using a selected group of processes for the method 700, there can be many alternatives, modifications, and variations. For example, some of the processes may be expanded and/or combined. Other processes may be inserted to those noted above. In another example, some of the processes may be replaced, removed, re-arranged, overlapped, and/or partially overlapped. Further details of these processes are found throughout the present specification and more particularly below.

At the process 710, a silicon wafer is provided. For example, the silicon wafer is undoped. In another example, the silicon wafer is doped (e.g., lightly doped or heavily doped) in either p-type or n-type characteristics for different embodiments. In yet another example, the process 710 is substantially the same as the process 610. At the process 712, ultra long silicon nanowires are formed. For example, a chemical etching process is performed to etch through the entire wafer thickness to produce the ultra long silicon nanowires. In another example, the chemical etching process also produce rough walls or micro-textures on the surfaces of the ultra long silicon nanowires. In another example, the ultra long silicon nanowires fall into the etch solution as a form of particles in mud. At the process 714, the ultra long silicon nanowires is recovered from the etch solution. For example, a recovery process is performed to collect the silicon nanowires from the etch solution. For example, various wet chemistry, filtering techniques, and/or centrifuge techniques are used to separate the silicon nanowires from the etch solution. In another example, the silicon nanowires are collected in a suspended particle form within isopropyl alcohol and/or simply separated as solid clusters. At the process 716, the collected silicon nanowires are dried. For example, the drying process is performed in an oven and/or a microwave. In another example, the drying process is performed to make solid clusters of silicon nanowires into a dried silicon nanowire powder.

At the process 734, the silicon nanowire powder is collected into a holder (e.g., a graphite holder with a predetermined shape and/or a predetermined size). At the process 740, the collected silicon nanowire powder is sintered to form a bulk-size nanostructured solid material. In one embodiment, the formed bulk-size nanostructured solid material is the same as the sheet of bulk-size material 200, the bulk-size nanostructured pellet 210, the bulk-size solid material 300, and the bulk-size solid material 400. In another embodiment, the sintering process is carried under certain conditions of temperature, pressure, time, temperature ramping speed, and/or pressure ramping speed, assisted by spark plasma and/or electric current, in a sealed chamber. In yet another embodiment, after the sintering process, the formed bulk-size nanostructured solid material is selectively inspected by microscope about its internal structure and evaluated by measuring its thermoelectric power density. For example, the sintering process can produce a bulk-size nanostructured solid material that is a wafer or disk with desired shape, lateral dimension, thickness, and/or density. In another example, the produced bulk-size nanostructured solid material includes interconnected nanostructures and bears a thermoelectric power density substantially higher than a bulk-size non-nanostructure solid material.

At the process 744, the formed bulk-size nanostructured solid material is polished and cleaned. For example, the process 744 is substantially the same as the process 644. At the process 750, the top surface and/or the bottom surface of the bulk-size nanostructured solid material is metalized. For example, the process 750 is substantially the same as the process 650. At the process 754, the bulk-size nanostructured solid material with the metalized top surface and/or the metalized bottom surface is annealed for thermal treatment. For example, the process 754 is substantially the same as the process 654. At the process 760, the bulk-size nanostructured solid material with a conductive contact layer on the top surface and/or a conductive contact layer on the bottom surface is diced into individual units each with a desired size. For example, the process 760 is substantially the same as the process 660. At the process 764, a thermoelectric module is assembled by arranging n-type legs and p-type legs in a multi-leg package. For example, the process 764 is substantially the same as the process 664.

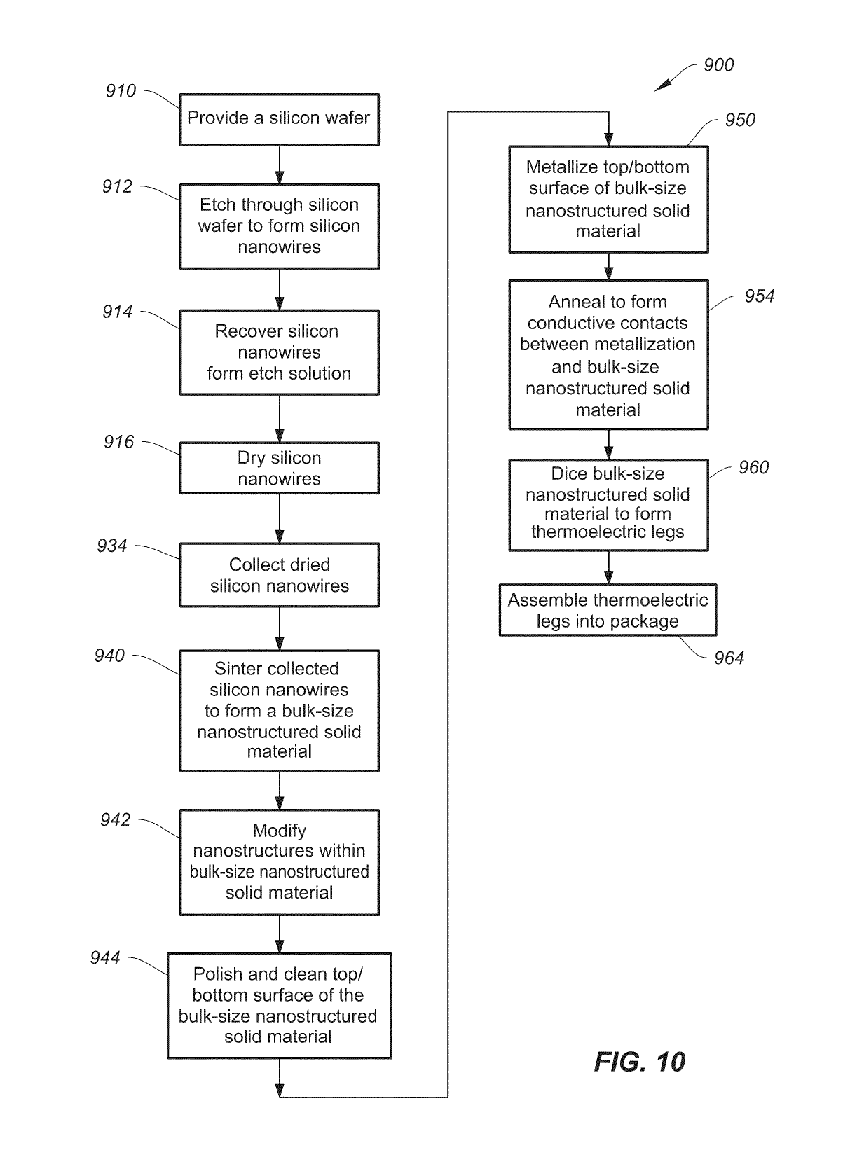

FIG. 9 is a simplified diagram showing a method for fabricating bulk-size nanostructured thermoelectric legs according to yet another embodiment of the present invention. This diagram is merely an example, which should not unduly limit the scope of the claims. One of ordinary skill in the art would recognize many variations, alternatives, and modifications. As shown in FIG. 9, the method 800 includes processes 810, 812, 814, 816, 834, 840, 842, 844, 850, 854, 860, and 864. Although the above has been shown using a selected group of processes for the method 800, there can be many alternatives, modifications, and variations. For example, some of the processes may be expanded and/or combined. Other processes may be inserted to those noted above. In another example, some of the processes may be replaced, removed, re-arranged, overlapped, and/or partially overlapped. Further details of these processes are found throughout the present specification and more particularly below.

At the process 810, a silicon wafer is provided. For example, the process 810 is substantially the same as the process 610 and/or the process 710. At the process 812, ultra long silicon nanowires are formed. For example, the process 812 is substantially the same as the process 712. At the process 814, the ultra long silicon nanowires is recovered from the etch solution. For example, the process 814 is substantially the same as the process 714. At the process 816, the collected silicon nanowires are dried into a silicon nanowire powder. For example, the process 816 is substantially the same as the process 716.

At the process 834, the silicon nanowire powder is collected into a holder (e.g., a graphite holder with a predetermined shape and/or a predetermined size). For example, the process 834 is substantially the same as the process 734. At the process 840, the collected silicon nanowire powder is sintered to form a bulk-size nanostructured solid material. For example, the process 840 is substantially the same as the process 740.

At the process 842, the bulk-size nanostructured solid material is modified with one or more fill materials. In one embodiment, the bulk-size nanostructured solid material formed at the process 840 is a porous material including nanowires interconnected with each other. In another example, at the process 842, the one or more fill materials are injected into interstitial regions (e.g., voids) between the nanowires. For example, this filling process is performed to enhance material density and/or tune thermal conductivity of the bulk-size nanostructured solid material. In another example, this filling process is performed to make the bulk-size nanostructured solid material into a more desirable thermoelectric material.

At the process 844, the formed bulk-size nanostructured solid material is polished and cleaned. For example, the process 844 is substantially the same as the process 644 and/or the process 744. At the process 850, the top surface and/or the bottom surface of the bulk-size nanostructured solid material is metalized. For example, the process 850 is substantially the same as the process 650 and/or the process 750. At the process 854, the bulk-size nanostructured solid material with the metalized top surface and/or the metalized bottom surface is annealed for thermal treatment. For example, the process 854 is substantially the same as the process 654 and/or the process 754. At the process 860, the bulk-size nanostructured solid material with a conductive contact layer on the top surface and/or a conductive contact layer on the bottom surface is diced into individual units each with a desired size. For example, the process 860 is substantially the same as the process 660 and/or the process 760. At the process 864, a thermoelectric module is assembled by arranging n-type legs and p-type legs in a multi-leg package. For example, the process 864 is substantially the same as the process 664 and/or the process 764.

As discussed above and further emphasized here, FIG. 9 is merely an example, which should not unduly limit the scope of the claims. One of ordinary skill in the art would recognize many variations, alternatives, and modifications. In one embodiment, after the process 816 but before the process 834, the silicon nanowire powder is mixed with one or more additional materials. For example, the mixing process is substantially the same as the process 630. In another example, the mixing process is added, so that, at the process 834, the mixed materials including the silicon nanowire powder and the one or more additional materials are collected into a holder (e.g., a graphite holder with a predetermined shape and/or a predetermined size), and at the process 640, the collected mixed materials are sintered to form a bulk-size nanostructured solid material.

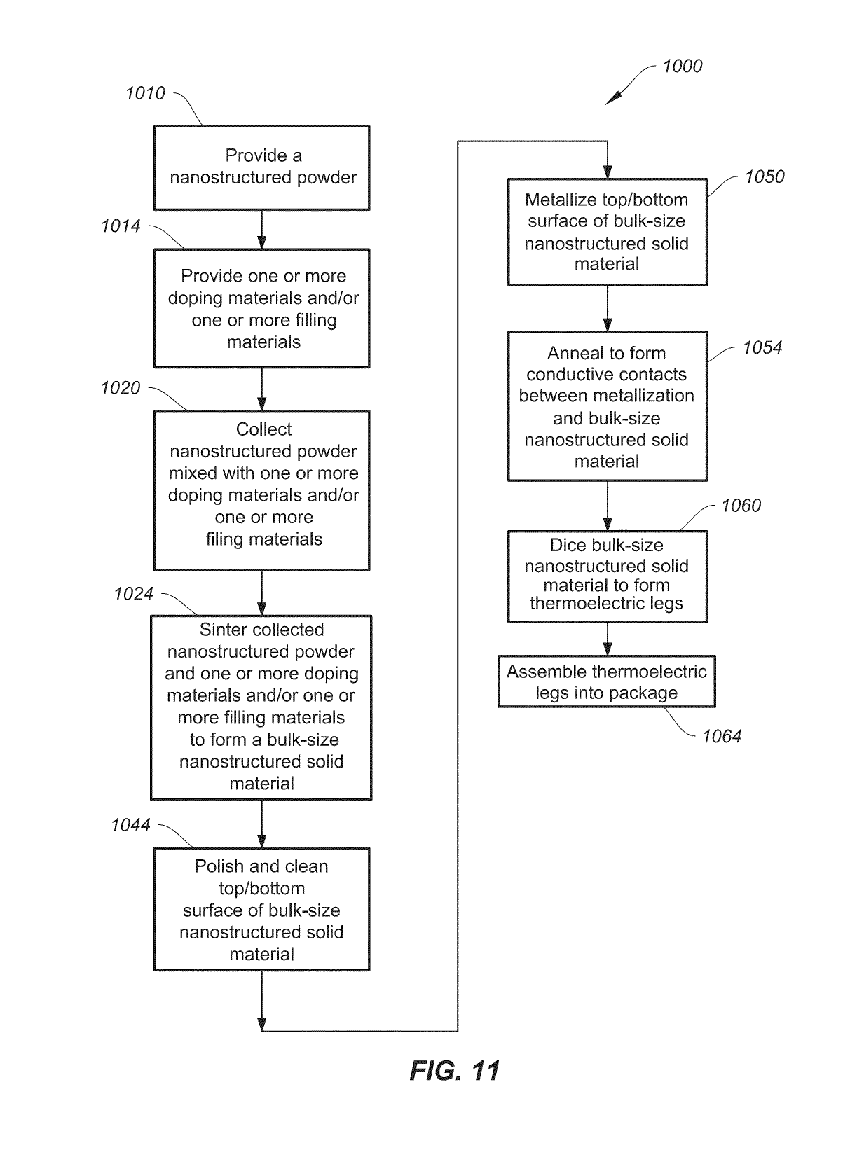

FIG. 10 is a simplified diagram showing a method for fabricating bulk-size nanostructured thermoelectric legs according to yet another embodiment of the present invention. This diagram is merely an example, which should not unduly limit the scope of the claims. One of ordinary skill in the art would recognize many variations, alternatives, and modifications. As shown in FIG. 10, the method 900 includes processes 910, 912, 914, 916, 934, 940, 942, 944, 950, 954, 960, and 964. Although the above has been shown using a selected group of processes for the method 900, there can be many alternatives, modifications, and variations. For example, some of the processes may be expanded and/or combined. Other processes may be inserted to those noted above. In another example, some of the processes may be replaced, removed, re-arranged, overlapped, and/or partially overlapped. Further details of these processes are found throughout the present specification and more particularly below.

At the process 910, a silicon wafer is provided. For example, the process 910 is substantially the same as the process 610, the process 710, and/or the process 810. At the process 912, ultra long silicon nanowires are formed. For example, the process 912 is substantially the same as the process 712 and/or the process 812. At the process 914, the ultra long silicon nanowires is recovered from the etch solution. For example, the process 914 is substantially the same as the process 714 and/or the process 814. At the process 916, the collected silicon nanowires are dried into a silicon nanowire powder. For example, the process 916 is substantially the same as the process 716 and/or the process 816. At the process 934, the silicon nanowire powder is collected into a holder (e.g., a graphite holder with a predetermined shape and/or a predetermined size). For example, the process 934 is substantially the same as the process 734 and/or the process 834. At the process 940, the collected silicon nanowire powder is sintered to form a bulk-size nanostructured solid material. For example, the process 940 is substantially the same as the process 740 and/or the process 840.

At the process 942, the bulk-size nanostructured solid material is modified with etching and/or passivation. In one embodiment, the bulk-size nanostructured solid material formed at the process 940 is a porous material including nanowires interconnected with each other. In another embodiment, the bulk-size nanostructured solid material formed at the process 940 is subjected to one or more etches at the process 942. For example, the one or more etches are performed by adding one or more etch solutions into interstitial regions (e.g., voids) between the nanowires. In another example, the one or more etch solutions are similar to the etch solution used to etch the silicon wafer at the process 912, such as liquid phase HF, AgNO₃. In yet another example, the one or more etches are performed through one or more gas-phase HF etches and/or one or more plasma etches. In yet another embodiment, at the process 942, the one or more etches are performed to roughen the walls of the nanowires and/or to make a silicon structure with nano-sized pores and/or holes. For example, the one or more etches are used to enhance the thermal conductivity. In another example, the one or more etches are used to preferentially etch the silicon crystal in one direction orthogonal to the nanowire axis so that the bulk-size nanostructured solid material are modified to include nanoribbons.

In yet another embodiment, the one or more etches are performed to at least partially remove SiO₂ (e.g., from surfaces of the silicon nanowires). For example, the removal of SiO₂ improves the electrical and corrosion properties of the bulk-size nanostructured solid material. In another example, after the removal of SiO₂, one or more passivation layers (e.g., dense Si₃N₄, dense SiO₂, dense Al₂O₃, and/or other type of dense insulator) are formed (e.g., on surfaces of the silicon nanowires) by atomic layer deposition and/or by saturation of the bulk-size nanostructured solid material in a liquid phase solution. In yet another embodiment, after the bulk-size nanostructured solid material (e.g., a nanostructured pellet) has been formed at the process 940, the process 942 is used to coat the surfaces of the interconnected silicon nanowires within the bulk-size nanostructured solid material with another thermoelectric material, and then to form one or more passivation layers over the surfaces of the interconnected silicon nanowires. In yet another embodiment, after the bulk-size nanostructured solid material (e.g., a nanostructured pellet) has been formed at the process 940, the process 942 is used to coat the surfaces of the interconnected silicon nanowires within the bulk-size nanostructured solid material with one or more reactive metals, and then to transform the interconnected silicon nanowires into metal-silicide nanowires before passivating the nanowires with one or more low-thermal conductivity materials.

At the process 944, the formed bulk-size nanostructured solid material is polished and cleaned. For example, the process 944 is substantially the same as the process 644, the process 744, and/or the process 844. At the process 950, the top surface and/or the bottom surface of the bulk-size nanostructured solid material is metalized. For example, the process 950 is substantially the same as the process 650, the process 750, and/or the process 850. At the process 954, the bulk-size nanostructured solid material with the metalized top surface and/or the metalized bottom surface is annealed for thermal treatment. For example, the process 954 is substantially the same as the process 654, the process 754, and/or the process 854. At the process 960, the bulk-size nanostructured solid material with a conductive contact layer on the top surface and/or a conductive contact layer on the bottom surface is diced into individual units each with a desired size. For example, the process 960 is substantially the same as the process 660, the process 760, and/or the process 860. At the process 964, a thermoelectric module is assembled by arranging n-type legs and p-type legs in a multi-leg package. For example, the process 964 is substantially the same as the process 664, the process 764, and/or the process 864.

As discussed above and further emphasized here, FIG. 10 is merely an example, which should not unduly limit the scope of the claims. One of ordinary skill in the art would recognize many variations, alternatives, and modifications. For example, the processes 910, 912, 914, 916, 934, and 940 are modified in order to make a nanostructured “skeleton” out of one or more non-thermoelectric materials, then at the process 942, one or more vapor-phase or liquid-phase depositions are used to coat the “skeleton” with one or more thermoelectric materials.

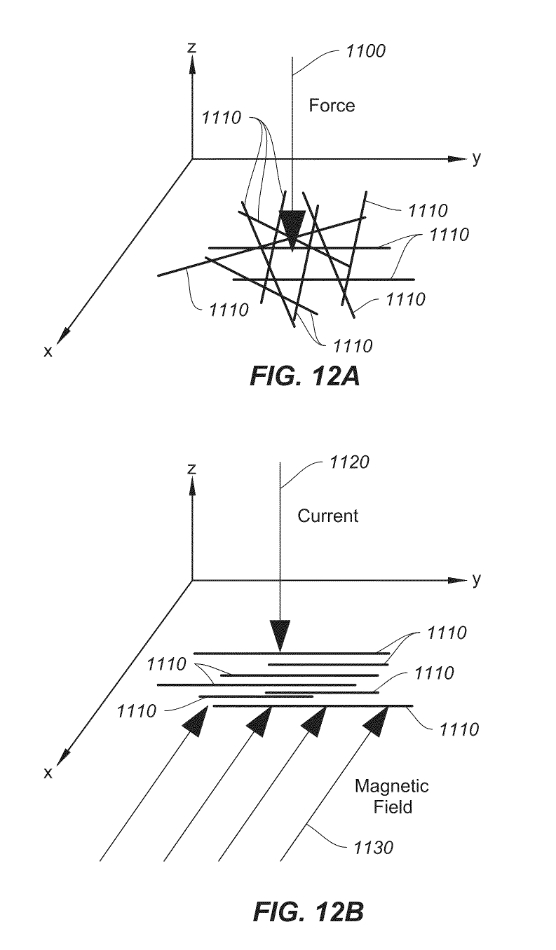

FIG. 11 is a simplified diagram showing a method for fabricating bulk-size nanostructured thermoelectric legs according to yet another embodiment of the present invention. This diagram is merely an example, which should not unduly limit the scope of the claims. One of ordinary skill in the art would recognize many variations, alternatives, and modifications. As shown in FIG. 11, the method 1000 includes processes 1010, 1014, 1020, 1024, 1044, 1050, 1054, 1060, and 1064. Although the above has been shown using a selected group of processes for the method 1000, there can be many alternatives, modifications, and variations. For example, some of the processes may be expanded and/or combined. Other processes may be inserted to those noted above. In another example, some of the processes may be replaced, removed, re-arranged, overlapped, and/or partially overlapped. Further details of these processes are found throughout the present specification and more particularly below.

At the process 1010, a nanostructured powder is provided. In one embodiment, the nanostructured powder is pre-fabricated out of one or more semiconductor materials (e.g., silicon, germanium) and/or one or more semimetal materials (e.g., a metal silicide). For example, the nanostructured powder is a silicon nanowire powder. In another example, the one or more semiconductor materials and/or the one or more semimetal materials are used for thermoelectric applications. In yet another example, the nanostructured powder includes one or more metallic materials mixed with one or more thermal insulating materials. In another embodiment, the nanostructured powder is provided from one or more commercial sources based on conventional thermoelectric materials.

At the process 1014, one or more doping materials and/or one or more filing materials are provided. For example, each of one or more doping materials and/or one or more filing materials includes a non-nanostructured metal and/or a nonmetal material. At the process 1020, the nanostructured powder mixed with the one or more doping materials and/or the one or more filing materials is collected into a holder (e.g., a graphite holder with a predetermined shape and/or a predetermined size). For example, the process 1020 is substantially the same as the process 634. In another example, the nanostructured powder and the one or more doping materials and/or the one or more filing materials are placed into the holder in a desired order to form functionally graded layers (e.g., in a predetermined multilayer configuration). In yet another example, the functionality of one or more nanostructured thermoelectric materials is properly arranged in the middle layers in situ with metal contact layers at two end regions. At the process 1024, the collected nanostructured powder and the one or more doping materials and/or the one or more filing materials are sintered to form a bulk-size nanostructured solid material. For example, the process 1024 is substantially the same as the process 640.

At the process 1044, the formed bulk-size nanostructured solid material is polished and cleaned. For example, the process 1044 is substantially the same as the process 644, the process 744, the process 844, and/or the process 944. At the process 1050, the top surface and/or the bottom surface of the bulk-size nanostructured solid material is metalized. For example, the process 1050 is substantially the same as the process 650, the process 750, the process 850, and/or the process 950. At the process 1054, the bulk-size nanostructured solid material with the metalized top surface and/or the metalized bottom surface is annealed for thermal treatment. For example, the process 1054 is substantially the same as the process 654, the process 754, the process 854, and/or the process 954. At the process 1060, the bulk-size nanostructured solid material with a conductive contact layer on the top surface and/or a conductive contact layer on the bottom surface is diced into individual units each with a desired size. For example, the process 1060 is substantially the same as the process 660, the process 760, the process 860, and/or the process 960. At the process 1064, a thermoelectric module is assembled by arranging n-type legs and p-type legs in a multi-leg package. For example, the process 1064 is substantially the same as the process 664, the process 764, the process 864, and/or the process 964.

As discussed above and further emphasized here, FIG. 11 is merely an example, which should not unduly limit the scope of the claims. One of ordinary skill in the art would recognize many variations, alternatives, and modifications. According to one embodiment, after the process 1024, the bulk-size nanostructured solid material is modified with one or more fill materials. For example, the one or more fill materials are filled into voids of the interconnected nanostructures for nanostructure enhancement and/or doping. In another example, the modification process is substantially the same as the process 842. According to another embodiment, after the process 1024, the bulk-size nanostructured solid material is modified with etching and/or passivation. For example, one or more etching and/or passivation processes are used to improve roughness and overall thermoelectric properties. In another example, the modification process is substantially the same as the process 942.

According to certain embodiments, spark plasma sintering (SPS) is used in the above methods for sintering one or more silicon nanowire powders and/or one or more other mixed-in materials. For example, a spark plasma sintering process (e.g., at a sintering temperature ranging from 600° C. to 1300° C.) can produce a bulk-size nanostructured wafer and/or pellet with a density that ranges from 40% to 100% of nanostructured material in its original form before sintering, while the wafer and/or pellet is also nanostructured.

Some embodiments of the present invention provide certain conditions for a sintering process (e.g., temperature and/or pressure of a spark plasma sintering process) for making a sintered pellet and/or wafer out of one or more silicon nanowire powders and/or one or more other relevant materials (e.g., to ensure a formation of interconnected nanowires). For example, specific conditions of a sintering process vary depending on types of nanostructured powders, doping levels, types of fill materials, and/or desired nanostructure treatment processes that are pre-sintering and/or post-sintering.

In one embodiment, the sintering temperature (e.g., a temperature for a spark plasma sintering process) ramps up at a rate higher than 100° C. per minute or lower than 100° C. per minute (e.g., at the beginning of the sintering process). For example, a lower ramp-up rate causes more agglomeration and/or fusing of nanowires. In another embodiment, after the temperature ramp-up, the dwell time at the peak temperature (e.g., the peak temperature ranging from 600° C. to 1300° C.) is less than 10 minutes. In yet another embodiment, after the dwell time, the temperature is reduced at a fast cooling rate. For example, the cooling rate allows one or more sintered objects to cool to around 50° C. in one hour or less.

According to one embodiment, the sintering pressure (e.g., a pressure applied during a spark plasma sintering process) ranges from about 5 MPa to about 100 MPa. For example, a higher sintering pressure is used to produce a bulk-size nanostructured pellet and/or wafer that has a higher density. In another example, a lower sintering pressure is used to produce a bulk-size nanostructured pellet and/or wafer that has a lower density. In yet another example, a higher sintering pressure is used to help radially align the silicon nanowires perpendicular to the direction of the pressure force.

In one embodiment, a sintering process (e.g., a spark plasma sintering process) is performed under a pressure ranging from 3 MPa to 7 MPa and a peak temperature ranging from 600° C. to 1400° C., with a sintering time of about 5 minutes or less. In another embodiment, a sintering process (e.g., a spark plasma sintering process) is performed under a pressure ranging from 10 MPa to 100 MPa and a peak temperature ranging from 600° C. to 900° C., with a sintering time less than 5 minutes. In yet another embodiment, a sintering process (e.g., a spark plasma sintering process) is performed under a pressure ranging from 3 MPa to 7 MPa and a peak temperature ranging from 600° C. to 900° C., with a sintering time ranging from 30 minutes to 600 minutes. In yet another embodiment, a sintering process (e.g., a spark plasma sintering process) is performed under a pressure ranging from 1 MPa to 10,000 MPa and a peak temperature ranging from 600° C. to 1500° C., with a sintering time ranging from 30 minutes to 600 minutes.

According to one embodiment, a nanostructured powder (e.g., a nanowire powder) is used as a to-be-sintered material. According to another embodiment, a paste including silicon nanowires and/or silicon nanoparticles suspended in a liquid is used as a to-be-sintered material. For example, the liquid burns off or evaporates off at low temperatures using a cure cycle (e.g., curing at 60° C. for 1 hour followed by ramping to 200° C. at a ramp-up rate of 5° C. per minute, and then annealing at 200° C. for 1 hour). In another example, after the cure cycle, a sintering process (e.g., a spark plasma sintering process) is performed as discussed above.

In some embodiments, the sintering processes described above can provide fused nanowires and/or interconnected nanostructures. For example, some control is achieved in selectively fusing nanostructures at certain locations with a desired level of fusing. In another example, orientation of the nanostructures within the bulk-size nanostructured material can be at least partially controlled. In certain embodiments, the sintering processes also includes one or more processes for controlling and/or modifying discontinuities in the nano-engineered material and/or for maintaining level of defects (e.g. holes).

According to one embodiment, a sintering process allows specific arrangement of powder materials to form a bulk-size functionally-graded thermoelectric material in situ with contact layers. For example, after sintering, the nanostructures within the bulk-size thermoelectric material can be processed with passivation and/or encapsulation materials that have already been created in-situ for the bulk-size material during the sintering process. In another example, the sintering process is performed in the atmosphere or in a reducing atmosphere (e.g., with added hydrogen and/or nitrogen, added formic acid, and/or other) to remove silicon oxide and/or other passivation layers from surfaces of the silicon nanowires. In yet another example, the sintering process is performed in vacuum, and then the sintered pellet and/or wafer is exposed to a gaseous-reducing and/or liquid-reducing environment to remove silicon oxides and/or other passivation layers from surfaces of the silicon nanowires. The removal or reduction of silicon oxides and/or other passivation layers can improve electrical and/or corrosion properties of the sintered pellet and/or wafer according to certain embodiments.

According to another embodiment, material sublimation is controlled by hermetic encapsulation in and/or after the sintering process. According to yet another embodiment, the sintering process can uses various process conditions to combine nanostructures in a way that retains specified physical characteristics of the nanostructures while allowing the nanostructures to be handled and manipulated as a bulk-size material. For example, density, porosity, grain size, and/or defects of the bulk-size nanostructured material are controlled.

According to yet another embodiment, the sintering process is used to make bulk-size solid materials that have good electrical contacts with contact materials and nanostructures that have insulating surface layers. For example, such good electrical contacts are achieved by using process conditions (e.g., high current density) and/or causing dielectric breakdown during the spark plasma sintering process. In another example, the sintering process can generate curved surfaces and form bulk-size solid materials with various cross-sectional shapes and/or cross-sectional areas to conform to other components with which the bulk-size solid materials will used as parts of thermoelectric devices.

In certain embodiments, the sintering process allows multiple materials, nanostructured and/or non-nanostructured, be incorporated together. For example, one or more materials serve as one or more functional thermoelectric materials, and one or more other materials serve as one or more filler materials. In another example, one or more materials are combined with one or more chemically reactive agents during the sintering process in order to produce another material that locally associated with the nanostructures, and/or in order to remove surface oxidation from the nanostructures (e.g., removing silicon oxide from surfaces of silicon nanowires). In yet another example, the sintered bulk-size solid material has controllable porosity which allows one or more materials to be filled after sintering in order to enhance the thermoelectric, thermal, electrical, mechanical, chemical, manufacturability, and/or corrosion properties of the final bulk-size composite material. In yet another example, the sintered bulk-size solid material is chemically processed after sintering (e.g. a chemical-roughening process after sintering) in order to enhance the performance of the nanostructures and also improve thermoelectric, thermal, electrical, mechanical, chemical, manufacturability, and/or corrosion properties of the final bulk-size composite material. In some embodiments, a sintering process is performed to include one or more techniques to tune and/or enhance alignment of the nanowires in a bulk-size nanostructured solid material that is formed by the sintering process.

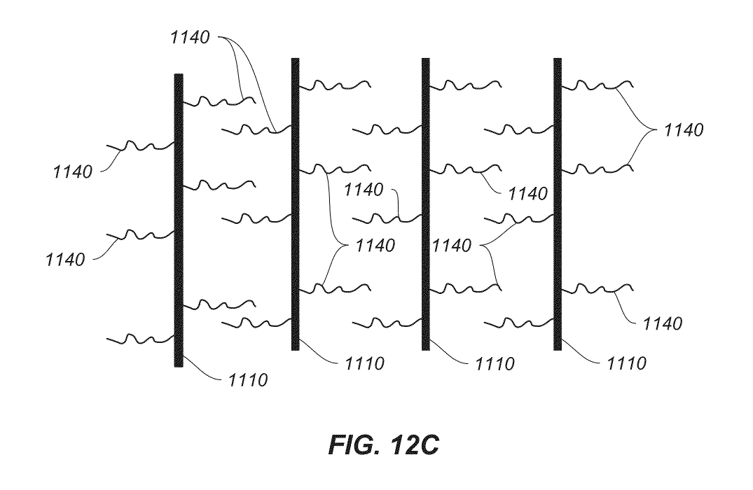

FIG. 12A is a simplified diagram showing a plurality of nanowires being partially aligned in a plane perpendicular to a direction of a sintering pressure applied during a sintering process according to one embodiment of the present invention. This diagram is merely an example, which should not unduly limit the scope of the claims. One of ordinary skill in the art would recognize many variations, alternatives, and modifications. For example, a sintering pressure 1100 is applied in a direction parallel to the z-axis. In another example, nanowires 1110 are aligned in a plane that is parallel to the x-axis and the y-axis and that is perpendicular to the sintering pressure 1100, although the nanowires 1110 within the plane are still in random orientations.

FIG. 12B is a simplified diagram showing a plurality of nanowires being aligned along a common direction by an electric current and a magnetic field applied during a sintering process according to another embodiment of the present invention. This diagram is merely an example, which should not unduly limit the scope of the claims. One of ordinary skill in the art would recognize many variations, alternatives, and modifications. In one embodiment, an electric current 1120 is applied in a direction parallel to the z-axis, a magnetic field 1130 is applied in a direction parallel to the x-axis, and the nanowires 1110 are aligned along a direction parallel to the y-axis. For example, the electric current 1120 flows through a nanostructured material (e.g., a nanowire powder) that is being sintered. In another example, the magnetic field 1130 is applied in the sintering tool. In another embodiment, by the Lorentz force, the applied magnetic field 1130 at least temporarily imposes a force to the nanowires 1110 with the electric current 1120.

As discussed above and further emphasized here, FIGS. 12A and 12B are merely examples, which should not unduly limit the scope of the claims. One of ordinary skill in the art would recognize many variations, alternatives, and modifications. For example, both the sintering pressure 1100 and the electric current 1120 are applied in the direction parallel to the z-axis, and the magnetic field 1130 is applied in the direction parallel to the x-axis, so that the nanowires 1110 are aligned not only in a plane that is parallel to the x-axis and the y-axis but also along a direction parallel to the y-axis.

FIG. 12C is a simplified diagram showing a plurality of nanowires being substantially aligned by a chemical repelling mechanism during a sintering process according to yet another embodiment of the present invention. This diagram is merely an example, which should not unduly limit the scope of the claims. One of ordinary skill in the art would recognize many variations, alternatives, and modifications. In one embodiment, the chemical repelling mechanism is performed by adding an anti-stiction agent and/or multiple long polar molecules 1140 to attach to the nanowires 1110, causing the nanowires 1110 to repel each other. For example, the nanowires 1110 seek out the minimum energy structure by being approximately aligned and evenly spaced. In another example, the chemical repelling mechanism is used as a chemical alignment technique, which may or may not be associated with the sintering process.

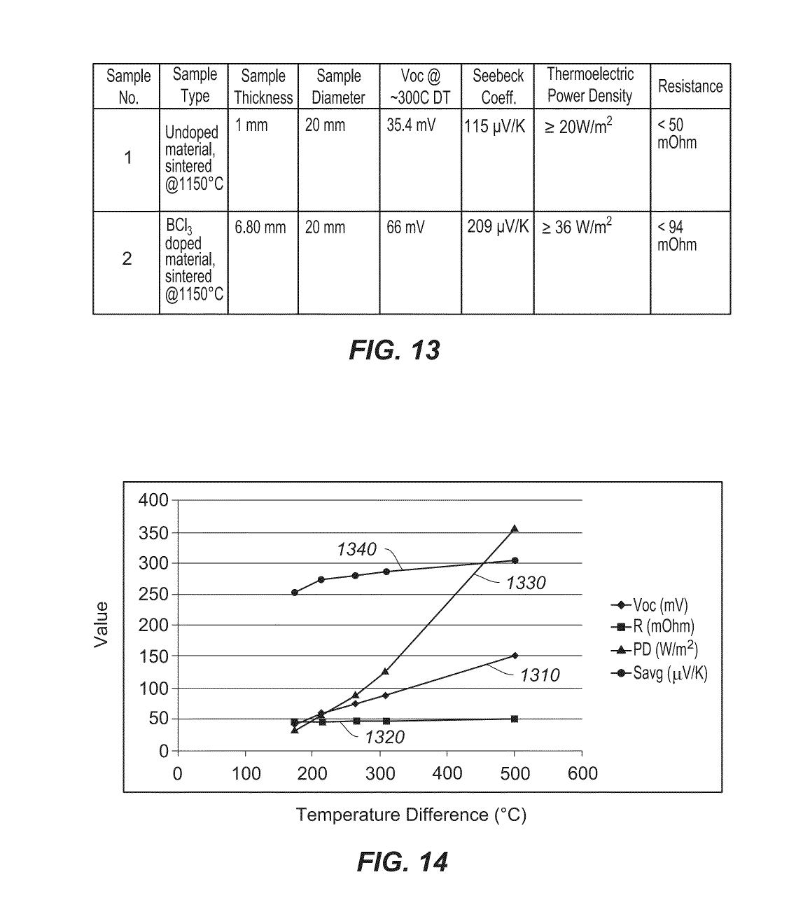

FIG. 13 is a simplified diagram showing measurement results for two samples of bulk-size nanostructured materials formed by sintering of one or more nanowire powders according to certain embodiments of the present invention. This diagram is merely an example, which should not unduly limit the scope of the claims. One of ordinary skill in the art would recognize many variations, alternatives, and modifications.

In one embodiment, sample 1 is a pellet with 1-mm thickness and 20-mm diameter, which has been made by sintering an undoped silicon nanowire powder at 1150° C. As shown in FIG. 13, sample 1 has an open-circuit voltage (e.g., V_{oc}) of about 35.4 mV measured with about 300° C. temperature difference across the thickness of sample 1, where the cold side of sample 1 is at the room temperature. Furthermore, sample 1 has a Seeback coefficient of about 115 μV/K, and a thermoelectric power density of at least about 20 W/m² with a resistance value smaller than 50 mOhm. In another embodiment, sample 2 is a pellet with 6.8-mm thickness and 20-mm diameter, which has been made by sintering a BCl₃-doped silicon nanowire powder at 1150° C. As shown in FIG. 13, sample 2 has an open-circuit voltage (e.g., V_{oc}) of about 66 mV measured with about 300° C. temperature difference across the thickness of sample 2, where the cold side of sample 2 is at the room temperature. Furthermore, sample 2 has a Seeback coefficient of about 209 μV/K, and a thermoelectric power density of at least about 36 W/m² with a resistance value smaller than 94 mOhm.

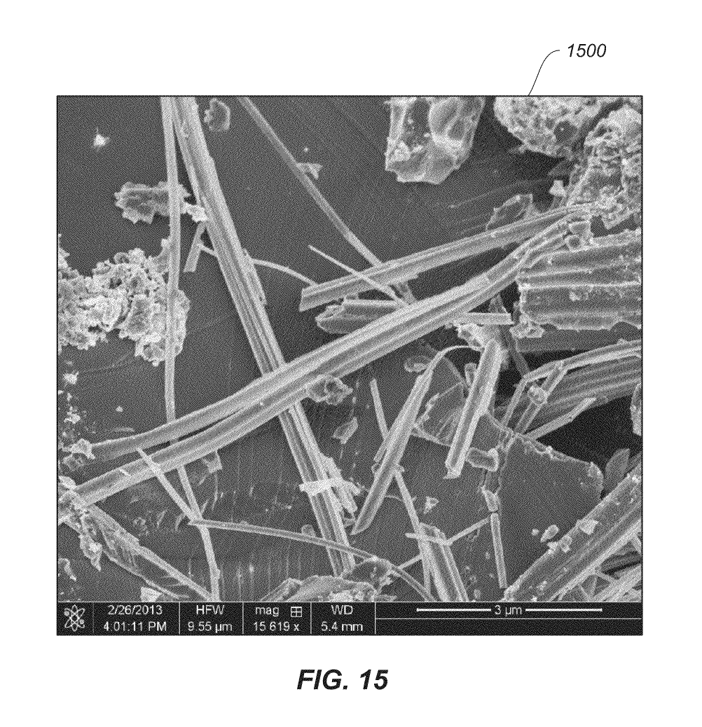

FIG. 14 is a simplified diagram showing thermoelectric measurement results for a bulk-size nanostructured material formed by sintering one or more nanowire powders according to some embodiments of the present invention. This diagram is merely an example, which should not unduly limit the scope of the claims. One of ordinary skill in the art would recognize many variations, alternatives, and modifications. In one embodiment, the bulk-size nanostructured material is a pellet with 6.8-mm thickness and 20-mm diameter, which has been made by sintering a boron-doped (e.g., BCl₃-doped) p-type silicon nanowire powder using a spark plasma sintering process. As shown in FIG. 14, the pellet is placed in a thermal junction having various temperature differences between the hot side and the cold side. Curve 1310 represents measured open-circuit voltage as a function of temperature difference between the hot side and the cold side, curve 1320 represents measured resistance as a function of temperature difference between the hot side and the cold side, curve 1330 represents thermoelectric power density as a function of temperature difference between the hot side and the cold side, and curve 1340 represents Seeback coefficient as a function of temperature difference between the hot side and the cold side.

In certain embodiments, the chamber environment when a pre-sintering sample (e.g., a silicon nanowire powder) is loaded into a spark plasma sintering (SPS) chamber and the chamber environment when a post-sintering sample (e.g., a bulk-size nanostructured solid material) is unloaded from the SPS chamber affect the thermoelectric properties of the bulk-size nanostructured solid material. For example, the silicon nanowire powder and the bulk-size nanostructured solid material can form silicon oxide at the room temperature, so it is desirable to load into and/or unload from an SPS chamber that has an inert environment (e.g., Ar, N₂, and/or He) or a vacuum environment. In another example, it is also desirable to load a pre-sintering sample (e.g., a silicon nanowire powder) into an SPS chamber as a paste material to ensure good contact to the SPS tooling.

According to one embodiment, the paste material incorporates an organic vehicle containing a surfactant to keep nanowires aligned, randomly oriented, or spaced in a controlled way in order to control the grain structure during sintering. For example, the organic vehicle includes a solvent (e.g. ethyl acetate) and a binder material (e.g., polypropylene carbonate). In another example, after the nanowires are suspended in the binder material, the nanowires are aligned along their axes by shear forces through ejection from a syringe and/or through screen printing. In yet another example, the ejection and/or the screen printing can make the resulting paste material into sheets or other pre-formed shapes that are convenient for use in the subsequent sintering process.

According to another embodiment, the following processes are performed: a) etch to form a silicon nanowire powder from a silicon wafer; b) dry the silicon nanowire powder; c) dope the silicon nanowire powder; d) scrape the doped silicon nanopowder off the wafer; e) disperse the silicon nanowire powder in a solvent; f) add a binder material to suspend the mixture of solvent and nanowire powder; g) eject and/or screen print the suspended nanowire powder into pellet pre-forms; and h) perform spark plasma sintering. For example, at process a), the silicon wafer is etched through the entire thickness of the wafer. In another example, process b) is replaced by a rinse/separating process.

In one embodiment, one or more silicon nanowire powders are loaded into an SPS chamber that contains one or more gas species, one or more liquid species, and/or one or more solid species that form a plasma in the presence of high current densities in excess of 1,000,000 A/m² and/or high temperatures above 600° C. For example, the plasma enhances surface characteristics of the one or more silicon nanowire powders, leading to a decrease in contamination and/or incorporation from oxides, nitrides, and/or organic materials. In another embodiment, a reducing gas (e.g., hydrogen) is introduced into the SPS chamber at an elevated temperature (e.g., above about 400° C.) to reduce metal oxides on metal nanoparticles that have been incorporated into the one or more silicon nanowire powders in order to improve electrical properties of the bulk-size nanostructured solid material after the sintering process. For example, nanoparticles can be functionalized to make them more or less likely to sinter. In another example, certain metals, alloys, ceramics, or refractory compounds deposited on the surface of the nanoparticles or mixed with the nanoparticles can enhance or inhibit the sintering of the nanoparticles.

In yet another embodiment, multiple bulk-size nanostructured materials are made at the same time in the same SPS chamber by stacking non-reactive spacers between layers of pre-sintering powders. For example, different bulk-size nanostructured materials made from different pre-sintering powders have the same or different compositions. In yet another embodiment, multiple bulk-size nanostructured materials are made at the same time in the same SPS chamber by putting different pre-sintering powders into different punches in the same tooling die. For example, the die and the punches are made of graphite though other materials such as tungsten carbide, alumina, quartz, or another refractory material can be used.

In another example, the entirety of a current flow can be forced to pass through the powders by using a nonconductive die, or by coating one or both of the punch surface and the die surface at each punch/die interface with a nonconductive material such as Al₂O₃. In yet another example, the entirety of a current can be forced to flow through the die by using a nonconductive spacer between the die and each punch and by using a nonconductive spacer between each punch and the powder within the punch. In yet another example, a nonconductive spacer is used between each punch and the powder within the punch, but each punch/die interface is kept conductive.

Other sintering techniques can be used to form a bulk-size nanostructured solid material according to certain embodiments. For example, hot isostatic pressing, capacitor discharge sintering, plasma sintering, and/or laser sintering can also produce thermoelectric materials from nanowire powders.

According to some embodiments, a pre-sintering powder for making a bulk-size nanostructured solid material is comprised of two or more types of nano-scale or micro-scale structures (e.g., microparticles, nanowires, nanospheres, nanotubes, nanoprisms, nanohorns, nanorods, nanocones, nanoshells, nanowhiskers, nanocombs, and/or nanodiscs). In one embodiment, an interactive mixture of silicon nanowires and inert nanoparticles (e.g., in the form of an inert nanopowder) is used to prevent the silicon nanowires from clumping together along the nanowire axes and from fusing to form a large grain with higher thermal conductivity than the un-sintered constituent nanowires. In another embodiment, an interactive mixture is used to induce a chemical reaction during the spark plasma sintering process, causing a layered structure of varying composition within the nanowires. In yet another embodiment, an interactive mixture of silicon nanowires and silicon nanoparticles is used to allow the silicon nanoparticles to stick to the surfaces of the silicon nanowires. For example, such interactive mixture can increase the number of contact points between silicon nanowires in order to improve electrical conductivity while retaining nano-scale roughened constrictions to impede the heat transfer.

According to certain embodiments, one or more in-situ doping processes are performed for a randomly or partially ordered mixture of nanowires and nanoparticles and/or an interactive mixture of nanowires and nanoparticles in order to form one or more desired functional thermoelectric materials. For example, the one or more desired functional thermoelectric materials are fabricated by using silicon nanowires mixed with one or more dopant materials (e.g., B or P₂O₅) in the form of micro-scale and/or nano-scale particles or other solid- or liquid-source dopants. In another example, the one or more dopant materials are placed near the silicon nanowire powder inside the SPS chamber, but not mixed with the silicon nanowire powder, in order to dope the silicon nanowire powder by proximity effect. In yet another example, the SPS chamber is back-filled with a dopant gas (e.g., phosphine or BCl₃), which would diffuse into the silicon nanowire powder during sintering.

According to some embodiments, the pre-sintering powder to be used for spark plasma sintering include silicon nanowires and/or other nanostructure species formed by further processing silicon nanowires. In one embodiment, the pre-sintering powder includes dumb-bell shaped nanostructures, each of which includes a silicon nanowire with one or more electrically active balls (e.g., one or more metal balls and/or one or more silicide balls) on one or both of its two ends. For example, the one or more metal balls and/or the one or more silicide balls are deposited on the silicon nanowire by a chemical vapor deposition process, a sputtering process, a liquid-phase electroless plating process, and/or a liquid-phase electroplating process. In another example, such dumb-bell shaped nanostructures can provide a desired material structure for sintering by controlling density and alignment of nanowires while ensuring good electrical contacts between the nanowires. In another embodiment, the pre-sintering powder includes dumb-bell shaped nanostructures, each of which includes a silicon nanowire with one or more inert balls on one or both of its two ends. For example, the one or more inert balls can effectively control the stacking of the nanowires and prevent aligned clusters of nanowires from sintering together along their axes to yield a higher thermal conductivity. In yet another embodiment, the pre-sintering powder includes silicon nanowires, for each of which, one or more desired materials are deposited in the middle of the nanowire and/or at several locations along the nanowire to help control the sintering process and prevent large grain formation while retaining a high number of electrical percolation paths and a high number of scattering sites for phonons.

According to one embodiment, the pre-sintering powder to be used for spark plasma sintering is treated prior to sintering in order to modify external surface topography, particle topology, and/or sizes of the powder species so that thermoelectric properties of post-sintering bulk-size nanostructured solid material are enhanced by modification of the phonon dispersion relationship, phonon density of states, band gap, carrier concentration, Fermi surface, and/or electron density of states. For example, by roughening edges of a silicon nanowire or a silicon nanotube, the thermal conductivity of the post-sintering nanostructured solid material is lowered. In another example, by causing partial amorphization of the outside surfaces of nanoparticles and/or partial regions of the post-sintering nanostructured solid material, the Seebeck coefficient is increased with effective thermal conductivity being reduced disproportionately to any reduction in electrical conductivity.

According to another embodiment, one or more processes are performed to lower thermal conductivity of post-sintering bulk-size nanostructured solid material by introducing local atomic lattice changes through phase segregation, incongruent melting, material precipitation, impurity doping, material removal, material sublimation, and/or density control during sintering. For example, silicon nanowires are mixed with Sn, Sb, and/or Mg, and the mixture is sintered under certain temperature and pressure conditions that cause one or more of Sn, Sb, and/or Mg to segregate near grain boundaries, introducing a scattering site for phonons. In another example, incongruent melting is used to cause segregation of one or more of Sn, Sb, and/or Mg from atomically mismatched layers within the post-sintering bulk-size nanostructured solid material. According to yet another embodiment, impurities are introduced during sintering to cause local lattice distortions, scattering sites, and/or changes in the phonon dispersion relationship to reduce the thermal conductivity. For example, sintering silicon nanowires with a heavy-element material (e.g., Pb) can cause local lattice distortions, scattering sites, and/or changes in the phonon dispersion relationship to reduce the thermal conductivity of post-sintering bulk-size nanostructured solid material.

According to yet another embodiment, one or more materials are reacted and/or dissolved into silicon nanowires prior to and/or during the sintering process, and then heated and/or cooled under controlled temperature and pressure so as to cause spinodal decomposition into nano-scale regions of varying chemical compositions. For example, boundaries and intrinsic properties of the layered regions are used to reduce the effective thermal conductivity of the bulk-size nanostructured solid material through high phonon scattering at interfaces and/or by changing the phonon dispersion relationship. In another example, a metal material is dissolved in the silicon nanowires at one temperature prior to sintering, and then the sintering process is performed under conditions that are chosen in such a way that the solid solution undergoes spinodal decomposition into a metal silicide and silicon leaving behind nano-scale regions of each composition.

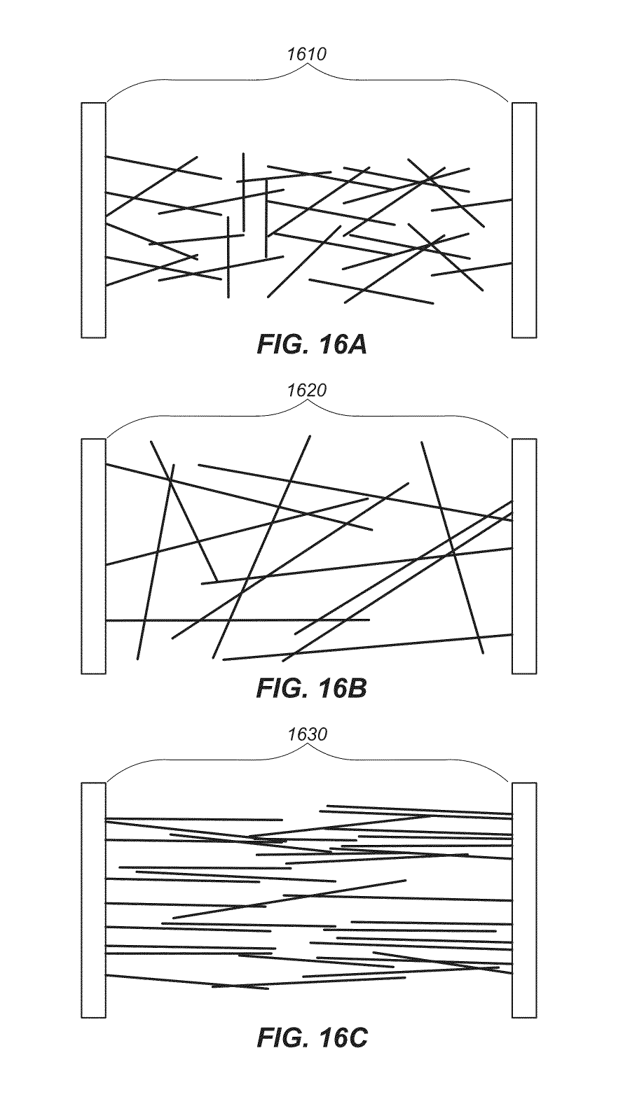

FIG. 15 is a simplified SEM image showing spontaneous formation of one or more controlled-size nano-scale and/or micro-scale lamellae of varying chemical compositions according to an embodiment of the present invention. This diagram is merely an example, which should not unduly limit the scope of the claims. One of ordinary skill in the art would recognize many variations, alternatives, and modifications. As shown by the SEM micrograph 1500 of nanowires, the spontaneous formation of one or more controlled-size nano-scale and/or micro-scale lamellae of varying chemical compositions is achieved by adding one or more materials to react with and/or dissolve into silicon nanowires prior to and/or during sintering, and then performing heating and/or cooling under controlled temperature and pressure. For example, the interfaces between the controlled-size nano-scale and/or micro-scale lamellae cause scattering of heat carriers, leading to reduced effective thermal conductivity of the bulk-size nanostructured solid material after the sintering process.

In one embodiment, one or more materials are dissolved into silicon nanowires prior to sintering and then sublimated from the solid solution during sintering, leaving behind nano-scale cavities that act as phonon scattering sites. For example, the one or more materials are one or more low-melting-point materials with high solid solubility in silicon. In another embodiment, certain material in a pre-sintering powder is removed through etching during sintering and/or after sintering, reducing characteristic sizes of the nanoparticles and/or nanoconstrictions within the bulk-size nanostructured solid material formed by the sintering process. For example, such removal leads to reduced thermal conductivity through enhanced phonon scattering. In yet another embodiment, a chemical reaction is induced within a powder (e.g., a silicon nanowire powder) during sintering to alter the material morphology. For example, the chemical reaction is a solid-assisted chemical reaction, a liquid-assisted chemical reaction, a gas-assisted chemical reaction, and/or a plasma-assisted chemical reaction. In another example, the chemical reaction is used to first oxidize and later reduce silicon nanowires so as to reduce sizes of the silicon nanowires and/or to enhance roughness of the silicon nanowires during sintering. In yet another example, the chemical reaction is used to alter the morphology of the bulk-size nanostructured solid material during the sintering process in order to achieve the desired thermoelectric properties.

According to some embodiments, adjusting strain level within a nanostructured powder (e.g., a silicon nanowire powder) during sintering (e.g., spark plasma sintering) facilitates reduction of thermal conductivity and/or enhancement of electrical conductivity of the bulk-size nanostructured solid material formed by the sintering process. In one embodiment, sintering conditions, powder compositions, powder production techniques, and/or sintering tooling (e.g., a SPS chamber) are selected in order to induce strain in order to enhance thermoelectric properties of the thermoelectric material formed by the sintering process. For example, the strain induced during sintering leads to modification of the phonon and electron density of states, leading to enhanced thermoelectric properties.

In another embodiment, compressive or tensile strain is introduced by layering materials with mismatched coefficients of thermal expansion. For example, the strain is made to line up along any axis of the bulk-size nanostructured solid material (e.g., along any axis of nanoparticles within the bulk-size nanostructured solid material) in order to achieve desired thermoelectric properties. In another example, the strain is induced within the bulk-size nanostructured solid material by forming one or more metal layers (e.g., one or more copper layers) with a high coefficient of thermal expansion on top and/or bottom of a layer of silicon nanowire powder during sintering, causing the metal layer to sinter to the silicon material and exert temperature-dependent stress on the bulk-size layer including silicon nanowires. In yet another example, the strain is induced within the bulk-size nanostructured solid material by mixing and at least partially aligning different powders with highly mismatching coefficients of thermal expansion prior to the sintering process, followed by a sintering process (e.g., a spark plasma sintering process) with predetermined temperature and pressure conditions.

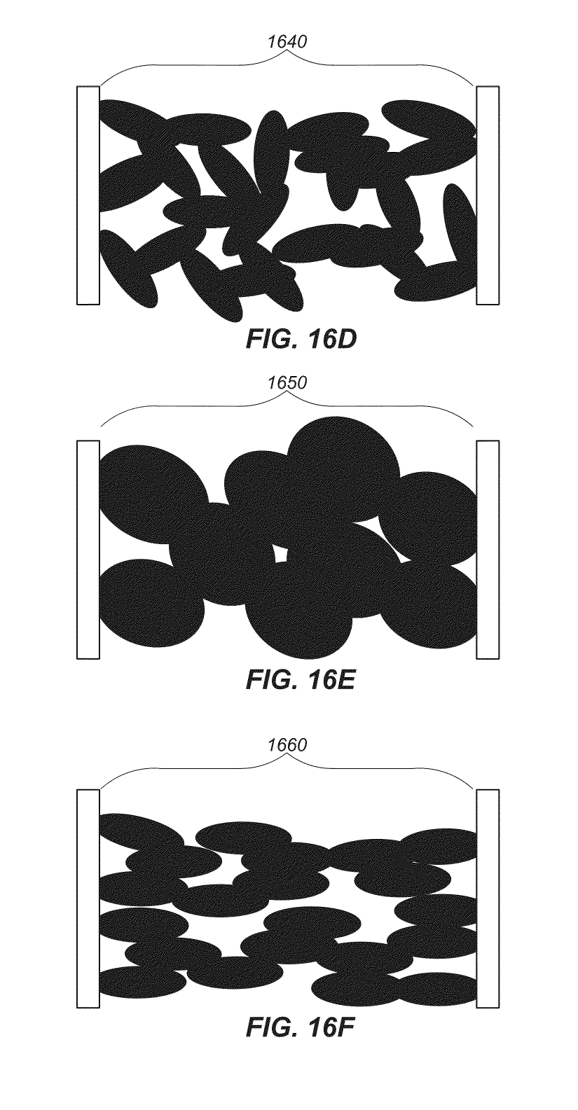

FIGS. 16A-F are simplified diagrams showing various configurations of nanowires, nanofibers, nanoparticles, and/or grains thereof in an interconnected structure formed between electrodes according certain embodiments of the present invention. These diagrams are merely examples, which should not unduly limit the scope of the claims. One of ordinary skill in the art would recognize many variations, alternatives, and modifications.

As shown in FIG. 16A, the bulk-size nanostructured material 1610 includes nanowires and/or nanofibers, with a density less than 100% of the nanostructured material in its original form before sintering (e.g., the bulk solid material without nanostructures). For example, the bulk-size nanostructured material 1610 has a short characteristic length, so the average distance along a nanowire between its connection with another nanowire and its another connection with yet another nanowire is also short, resulting in high contact resistance per volume of the bulk-size nanostructured material 1610.

As shown in FIG. 16B, the bulk-size nanostructured material 1620 includes nanowires and/or nanofibers, with a density less than 100% of the nanostructured material in its original form before sintering (e.g., the bulk solid material without nanostructures). For example, the bulk-size nanostructured material 1620 has a long characteristic length, so the average distance along a nanowire between its connection with another nanowire and its another connection with yet another nanowire is also long, resulting in low contact resistance per volume of the bulk-size nanostructured material 1620.

As shown in FIG. 16C, the bulk-size nanostructured material 1630 includes nanowires and/or nanofibers, with a density less than 100% of the nanostructured material in its original form before sintering (e.g., the bulk solid material without nanostructures). For example, the nanowires are aligned such that the axes of the nanowires are substantially along the direction of thermal and electronic transport, reducing losses due to impedance mismatch through a tortuous thermoelectric circuit in a fixed temperature gradient and voltage.

As shown in FIG. 16D, the bulk-size nanostructured material 1640 includes nanoparticles, with a density less than 100% of the nanostructured material in its original form before sintering (e.g., the bulk solid material without nanostructures). For example, the bulk-size nanostructured material 1640 has a short characteristic length, so the average distance along the length of a nanoparticle between its connection with another nanoparticle and its another connection with yet another nanoparticle is also short, resulting in high contact resistance per volume of the bulk-size nanostructured material 1640.

As shown in FIG. 16E, the bulk-size nanostructured material 1650 includes nanoparticles, with a density less than 100% of the nanostructured material in its original form before sintering (e.g., the bulk solid material without nanostructures). For example, the bulk-size nanostructured material 1650 has a long characteristic length, so the average distance along the length of a nanoparticle between its connection with another nanoparticle and its another connection with yet another nanoparticle is also long, resulting in low contact resistance per volume of the bulk-size nanostructured material 1650.

As shown in FIG. 16F, the bulk-size nanostructured material 1660 includes nanoparticles, with a density less than 100% of the nanostructured material in its original form before sintering (e.g., the bulk solid material without nanostructures). For example, the nanoparticles are aligned such that the axes of the nanoparticles are substantially along the direction of thermal and electronic transport, reducing losses due to impedance mismatch through a tortuous thermoelectric circuit in a fixed temperature gradient and voltage.

According to another embodiment, a bulk-size nano-composite material includes a first solid material including a plurality of particles. Each particle includes one or more continuous structural features characterized by a width across from one solid surface to another in a first direction, a length measured away from the first direction continuously from one solid end to another, and a spacing between a solid surface/end to a separate solid surface/end of the same particle or from neighboring particles. The length is greater than 400 μm, the width throughout the length is within a range from 1 nm to 1000 nm, and the spacing ranges from 10 nm to 10 μm. The plurality of particles is operably packed under a sintering condition in association with high current densities in excess of 1,000,000 A/m² and/or high temperatures above 600° C. to form at least one first region and at least one second region within a bulk-size body having at least one dimension greater than a few millimeters. The at least one first region is occupied by the first solid material with two or more particles being interconnected at one or more solid surfaces/ends to establish electrical contacts but maintaining thermal conductivity of the bulk-size body below 25 Watts per meter per degree Kelvin. The at least one second region is left as a void or is configured to be occupied by one or more secondary materials.

For example, the first solid material is a semiconductor material. In another example, the first solid material includes silicon and/or germanium. In yet another example, the particles include one type of nanostructure selected from nanowires, nanospheres, nanotubes, nanoprisms, nanohorns, nanorods, nanocones, nanoshells, nanowhiskers, nanocombs, and nanodiscs. In yet another example, the first region includes interconnected nanowires being partially aligned in one direction by a Lorentz force. In yet another example, the first region includes interconnected nanowires being substantially laid within a plane by a pressure force. In yet another example, the first region includes interconnected nanowires being substantially aligned by chemical suspension forces provided by a liquid solution in the second region.

In yet another example, the one or more secondary materials includes a solid powder form with particle sizes less than 10 μm, wherein the one or more secondary materials are mixed with the first solid material or disposed in a layer separate from the first solid material. In yet another example, the one or more secondary materials include a solid powder form with particle sizes less than 10 μm, and the one or more secondary materials are disposed in a layer separate from the first solid material. In yet another example, the one or more secondary materials include a liquid for suspending the plurality of particles and retained within the at least one second region. In yet another example, the one or more secondary materials are in a gaseous form including air to fill the at least one second region. In yet another example, the one or more secondary materials include a dopant being doped into the plurality of particles, including either N-type or P-type semiconductor characteristics. In yet another example, the one or more secondary materials include a metal, a metal alloy, a metal oxide, a metal silicide, or a combination of those in powdered form for being combined into the plurality of particles. In yet another example, the one or more secondary materials include a dielectric material including air, oxide, and/or ceramic that is characterized by a thermal conductivity less than 50 Watts per meter per degree Kelvin and fills substantially the at least one second region. In yet another example, the one or more secondary materials include a plurality of second particles having substantially the same sizes as the particles of the first solid material, and each of the second particles is at an interstitial region of the plurality of particles. In yet another example, the one or more secondary materials include a plurality of second particles having substantially smaller sizes than the particles of the first solid material, and each of the second particles are stick on the solid surfaces of the plurality of particles. In yet another example, the one or more secondary materials and the first solid material is subjected to a chemical reaction to form the solid material for occupying the at least one first region as the bulk-size shape is operably packed.

According to yet another embodiment, a method for forming a bulk-size thermoelectric leg using a nano-composite material includes providing a first solid material prefabricated to a form of a plurality of particles. Each particle includes one or more continuous structural features characterized by a width across from one solid surface to another in a first direction, a length measured away from the first direction continuously from one solid end to another, and a spacing between a solid surface/end to a separate solid surface/end of the same particle or from neighboring particles. The length is greater than 400 the width throughout the length is within a range from 1 nm to 1000 nm, and the spacing is ranged from 10 nm to 10 μm. Additionally, the method includes disposing the first solid material and optional one or more secondary materials in a predetermined multilayer configuration as a paste material, and sintering the paste material along a direction perpendicular to the multilayer configuration under an assistance of an electric current in association with high current densities in excess of 1,000,000 A/m² and/or high temperatures above 600° C. to form a bulk-size body having at least a dimension within the layers being greater than a few millimeters. The bulk-size body includes at least one first region and at least one second region. The at least one first region is occupied by solid material formed at least from two particles interconnected at one or more solid surfaces/ends to establish electrical contacts and the at least one second region is occupied by the one or more secondary materials or left as a void.

For example, the process of providing a first solid material includes etching a silicon wafer to form a plurality of silicon nanowires characterized by lengths over 400 μm, doping the silicon nanowires, and scraping the silicon nanowires out of the silicon wafer as a powder. In another example, the paste material is suspended by an organic vehicle including an ethyl acetate solvent and a polypropylene carbonate binder material.

According to yet another embodiment, a sintered bulk solid material is provided, whose grains electrically, thermally, and/or mechanically contact one another at one or more locations on their surfaces throughout the structure to form an interconnected network, wherein these grains include discrete wires, fibers, particles, or pluralities thereof with dimensions in each direction between 1 and 1000 nm.

According to yet another embodiment, a nanobulk material can be formed by sintering nanostructured silicon powders to create a bulk-size solid with interconnected nanostructures for the manufacture of thermoelectric devices. For example, nanostructured silicon material can be pre-fabricated through many processes including etching, deposition, thin-film growth, and others. In another example, silicon nanowires or nanoholes with 400 μm or greater in length scale are produced over a whole wafer level and are collected in powder or cluster forms.

Certain embodiments of the present invention provide methods of making a bulk-size nanostructured thermoelectric material from a plurality of nanostructured powders or clusters. For example, the thermoelectric properties of the bulk-size nanostructured solid material according to embodiments of the present invention are better than conventional bulk silicon material that is not nanostructured. In another example, the methods of making the bulk-size nanostructured thermoelectric material according to embodiments of the present invention are easy to manufacture and process, posting many advantages over conventional ways of making large scale nanostructured material.

Some embodiments of the present invention provide structures and methods for bulk-size solid materials with interconnected nanostructures in various of shapes, sizes, thickness, and densities. For example, the nanostructures contained in the bulk-size solid can be randomly connected, micro-fused together, or partially restrained in a plane or partially aligned in a direction. In another example, the nanostructures are configured to have thermoelectric functionality with a low thermal conductivity and high electrical conductivity. In yet another example, methods for forming such bulk solid material include a formation of various types of nanostructures from raw semiconductor/semimetal materials and a transfer of the nanostructured material in a form of powders or clusters, and a sintering of the nanostructured powders, with or without additional fill materials or dopants, into a shaped bulk solid material in which the nanostructures are caused to substantially interconnect to each other. For example, the shaped bulk solid material with interconnected nanostructures can be further modified and diced into a plurality of bulk-size nanostructured thermoelectric legs.

According to yet another embodiment, a thermoelectric solid material includes a plurality of nanowires. Each nanowire of the plurality of nanowires corresponds to an aspect ratio (e.g., a ratio of a length of a nanowire to a diameter of the nanowire) equal to or larger than 10, and each nanowire of the plurality of nanowires is chemically bonded to one or more other nanowires at at least two locations of the each nanowire. For example, the thermoelectric solid material is described in at least FIG. 2A, FIG. 2B, FIG. 3A, FIG. 3B, FIG. 4, FIG. 5A, FIG. 5B, FIG. 6A, FIG. 6B, FIG. 12A, FIG. 12B, FIG. 12C, FIG. 13, FIG. 14, FIG. 15, FIG. 16A, FIG. 16B, FIG. 16C, FIG. 16D, FIG. 16E, and/or FIG. 16F. In another example, the thermoelectric solid material is made according to at least FIG. 7, FIG. 8, FIG. 9, FIG. 10, and/or FIG. 11.

In yet another example, the thermoelectric solid material includes a first continuous surface and a second continuous surface, the thermoelectric solid material is associated with a thickness from the first continuous surface to the second continuous surface, and the thickness is larger than 50 μm. In yet another example, the thickness is larger than 100 μm. In yet another example, the thickness is larger than 1 mm. In yet another example, the first continuous surface is associated with a first dimension larger than 100 μm in a first direction and a second dimension larger than 100 μm in a second direction, and the second continuous surface is associated with a third dimension larger than 100 μm in a third direction and a fourth dimension larger than 100 μm in a fourth direction. The second direction is perpendicular to the first direction, and the fourth direction is perpendicular to the third direction. In yet another example, the thermoelectric solid material is configured to be used in a thermoelectric device to generate electricity in response to a temperature difference between the first continuous surface and the second continuous surface based on the Seebeck effect. In yet another example, the thermoelectric solid material is configured to be used in a thermoelectric device to pump heat from the first continuous surface to the second continuous surface based on the Peltier effect. In yet another example, the thermoelectric solid material is associated with a thermoelectric figure of merit ZT larger than 0.1 at a temperature high than 300° C. in an ambient including oxygen and nitrogen. In yet another example, the thermoelectric figure of merit ZT is larger than 0.1 at the temperature high than 600° C. in the ambient including the oxygen and the nitrogen.

According to yet another embodiment, a thermoelectric solid material includes a multiply connected structure including a plurality of structural components and a plurality of connection components. The plurality of structural components are connected by the plurality of connection components. The plurality of structural components and the plurality of connection components include one or more first materials, each connection component of the plurality of connection components corresponds to an aspect ratio (e.g., a ratio of a length of a connection component to a width of the connection component) equal to or larger than 10, each connection component of the plurality of connection components is separated from a structural component or another connection component by one or more voids, and the one or more voids correspond to a thermal conductivity less than 5 W/m-K. The thermoelectric solid material is associated with a first volume, the plurality of structural components and the plurality of connection components are associated with a second volume, and a ratio of the second volume to the first volume ranges from 20% to 99.9%. The thermoelectric solid material is associated with a thermoelectric figure of merit ZT larger than 0.1. For example, the thermoelectric solid material is described in at least FIG. 2A, FIG. 2B, FIG. 3A, FIG. 3B, FIG. 4, FIG. 5A, FIG. 5B, FIG. 6A, FIG. 6B, FIG. 12A, FIG. 12B, FIG. 12C, FIG. 13, FIG. 14, FIG. 15, FIG. 16A, FIG. 16B, FIG. 16C, FIG. 16D, FIG. 16E, and/or FIG. 16F. In another example, the thermoelectric solid material is made according to at least FIG. 7, FIG. 8, FIG. 9, FIG. 10, and/or FIG. 11.

In yet another example, the one or more voids are filled by one or more oxide materials. In yet another example, the one or more voids are filled by air. In yet another example, the one or more voids are one or more vacuums. In yet another example, the one or more first materials are thermoelectric, the one or more voids are filled by one or more second materials, and the one or more second materials are thermoelectric and different from the one or more first materials.

According to yet another embodiment, a thermoelectric solid material includes a plurality of silicon grains. Each grain of the plurality of silicon grains is smaller than 250 nm in any dimension, and each grain of the plurality of silicon grains corresponds to an aspect ratio (e.g., a ratio of a length of a silicon grain to a width of the silicon grain) equal to or larger than 10. For example, the thermoelectric solid material is described in at least FIG. 2A, FIG. 2B, FIG. 3A, FIG. 3B, FIG. 4, FIG. 5A, FIG. 5B, FIG. 6A, FIG. 6B, FIG. 12A, FIG. 12B, FIG. 12C, FIG. 13, FIG. 14, FIG. 15, FIG. 16A, FIG. 16B, FIG. 16C, FIG. 16D, FIG. 16E, and/or FIG. 16F. In another example, the thermoelectric solid material is made according to at least FIG. 7, FIG. 8, FIG. 9, FIG. 10, and/or FIG. 11.

In yet another example, the plurality of silicon grains occupy less than 90% of the total volume of the thermoelectric solid material. In yet another example, the thermoelectric solid material is associated with a thermoelectric figure of merit ZT larger than 0.1. In yet another example, each grain of the plurality of silicon grains is smaller than 250 nm in length, width, and height.

According to yet another embodiment, a thermoelectric solid material includes a plurality of nanostructures. The thermoelectric solid material is associated with a Hausdorff dimension larger than zero and smaller than three, and the thermoelectric solid material is associated with a thermoelectric figure of merit ZT larger than 0.1. For example, the thermoelectric solid material is described in at least FIG. 2A, FIG. 2B, FIG. 3A, FIG. 3B, FIG. 4, FIG. 5A, FIG. 5B, FIG. 6A, FIG. 6B, FIG. 12A, FIG. 12B, FIG. 12C, FIG. 13, FIG. 14, FIG. 15, FIG. 16A, FIG. 16B, FIG. 16C, FIG. 16D, FIG. 16E, and/or FIG. 16F. In another example, the thermoelectric solid material is made according to at least FIG. 7, FIG. 8, FIG. 9, FIG. 10, and/or FIG. 11.

According to yet another embodiment, a method for making a thermoelectric solid material includes providing a plurality of nanowires. Each nanowire of the plurality of nanowires is in contact with at least another nanowire of the plurality of nanowires. Additionally, the method includes sintering the plurality of nanowires under a temperature higher than 25° C. or under a pressure higher than 760 torr to form the thermoelectric solid material. For example, the method is implemented according to at least FIG. 7, FIG. 8, FIG. 9, FIG. 10, and/or FIG. 11. In another example, the method is used to make a thermoelectric solid material as described in at least FIG. 2A, FIG. 2B, FIG. 3A, FIG. 3B, FIG. 4, FIG. 5A, FIG. 5B, FIG. 6A, FIG. 6B, FIG. 12A, FIG. 12B, FIG. 12C, FIG. 13, FIG. 14, FIG. 15, FIG. 16A, FIG. 16B, FIG. 16C, FIG. 16D, FIG. 16E, and/or FIG. 16F.

In yet another example, the sintering the plurality of nanowires includes forming, by diffusion, one or more chemical bonds between at least two nanowires of the plurality of nanowires. In yet another example, the sintering the plurality of nanowires is performed under the temperature higher than 25° C. and the pressure higher than 760 torr to form the thermoelectric solid material. In yet another example, the sintering the plurality of nanowires includes heating the plurality of nanowires by at least applying an electric current to the plurality of nanowires. In yet another example, the sintering the plurality of nanowires includes heating the plurality of nanowires by at least using a furnace.

In yet another example, the providing a plurality of nanowires includes etching one or more parts of a silicon substrate to form the plurality of nanowires. In yet another example, the method further includes providing a plurality of nanoparticles. In yet another example, the providing a plurality of nanowires and the providing a plurality of nanoparticles are performed by at least providing a mixture of the plurality of nanowires and the plurality of nanoparticles. In yet another example, the method further includes doping the plurality of nanowires with the plurality of nanoparticles. In yet another example, the method further includes hindering the sintering of the plurality of nanowires by at least the plurality of nanoparticles. In yet another example, the method further includes assisting the sintering of the plurality of nanowires by at least the plurality of nanoparticles. In yet another example, the sintering the plurality of nanowires includes sintering the plurality of nanowires and the plurality of nanoparticles under the temperature higher than 25° C. or under the pressure higher than 760 torr to form the thermoelectric solid material. In yet another example, the sintering the plurality of nanowires includes performing one or more chemical reactions between the plurality of nanowires and the plurality of nanoparticles.

In yet another example, the providing a plurality of nanowires includes providing the plurality of nanowires embedded within a matrix, the matrix including one or more fill materials located between the plurality of nanowires, and the sintering the plurality of nanowires includes sintering the matrix including the plurality of nanowires and the one or more fill materials. In yet another example, the providing a plurality of nanowires includes providing one or more first nanowires of a first type and one or more second nanowires of a second type, and the sintering the plurality of nanowires includes sintering the one or more first nanowires and the one or more second nanowires. The second type is different from the first type. In yet another example, the providing a plurality of nanowires includes providing a first layer of one or more first nanowires of a first type and a second layer, and the sintering the plurality of nanowires includes sintering the first layer of the one or more first nanowires and the second layer. In yet another example, the second layer includes one or more second nanowires of a second type, and the second type is different from the first type. In yet another example, the second layer includes one or more conductive materials, and the sintering the first layer of the one or more first nanowires and the second layer includes forming the thermoelectric solid material including the sintered second layer of the one or more conductive materials.

According to yet another embodiment, a thermoelectric solid material made by a process. The process includes providing a plurality of nanowires, each nanowire of the plurality of nanowires being in contact with at least another nanowire of the plurality of nanowires, and sintering the plurality of nanowires under a temperature higher than 25° C. or under a pressure higher than 760 torr to form the thermoelectric solid material. For example, the thermoelectric solid material is described in at least FIG. 2A, FIG. 2B, FIG. 3A, FIG. 3B, FIG. 4, FIG. 5A, FIG. 5B, FIG. 6A, FIG. 6B, FIG. 12A, FIG. 12B, FIG. 12C, FIG. 13, FIG. 14, FIG. 15, FIG. 16A, FIG. 16B, FIG. 16C, FIG. 16D, FIG. 16E, and/or FIG. 16F. In another example, the thermoelectric solid material is made according to at least FIG. 7, FIG. 8, FIG. 9, FIG. 10, and/or FIG. 11.

Although specific embodiments of the present invention have been described, it will be understood by those of skill in the art that there are other embodiments that are equivalent to the described embodiments. For example, various embodiments and/or examples of the present invention can be combined. Accordingly, it is to be understood that the invention is not to be limited by the specific illustrated embodiments, but only by the scope of the appended claims.

What is claimed is:

1. A thermoelectric solid material, the thermoelectric solid material comprising:
a plurality of nanowires, wherein:
each nanowire of the plurality of nanowires corresponds to an aspect ratio equal to or larger than 10; and
each nanowire of the plurality of nanowires is chemically bonded to one or more other nanowires at at least two locations of the each nanowire.

2. The thermoelectric solid material of claim 1 wherein:
the thermoelectric solid material includes a first continuous surface and a second continuous surface;
the thermoelectric solid material is associated with a thickness from the first continuous surface to the second continuous surface; and
the thickness is larger than 50 μm.

3. The thermoelectric solid material of claim 2 wherein the thickness is larger than 100 μm.

4. The thermoelectric solid material of claim 3 wherein the thickness is larger than 1 mm.

5. The thermoelectric solid material of claim 2 wherein:
the first continuous surface is associated with a first dimension larger than 100 μm in a first direction and a second dimension larger than 100 μm in a second direction, the second direction being perpendicular to the first direction; and
the second continuous surface is associated with a third dimension larger than 100 μm in a third direction and a fourth dimension larger than 100 μm in a fourth direction, the fourth direction being perpendicular to the third direction.

6. The thermoelectric solid material of claim 2 is configured to be used in a thermoelectric device to generate electricity in response to a temperature difference between the first continuous surface and the second continuous surface based on the Seebeck effect.

7. The thermoelectric solid material of claim 2 is configured to be used in a thermoelectric device to pump heat from the first continuous surface to the second continuous surface based on the Peltier effect.

8. The thermoelectric solid material of claim 1 wherein the thermoelectric solid material is associated with a thermoelectric figure of merit ZT larger than 0.1 at a temperature high than 300° C. in an ambient including oxygen and nitrogen.

9. The thermoelectric solid material of claim 1 wherein the thermoelectric figure of merit ZT is larger than 0.1 at the temperature high than 600° C. in the ambient including the oxygen and the nitrogen.

10. A thermoelectric solid material, the thermoelectric solid material comprising:
a multiply connected structure including a plurality of structural components and a plurality of connection components, the plurality of structural components being connected by the plurality of connection components;
wherein:
the plurality of structural components and the plurality of connection components include one or more first materials;
each connection component of the plurality of connection components corresponds to an aspect ratio equal to or larger than 10;
each connection component of the plurality of connection components is separated from a structural component or another connection component by one or more voids; and
the one or more voids correspond to a thermal conductivity less than 5 W/m-K;
wherein:
the thermoelectric solid material is associated with a first volume;
the plurality of structural components and the plurality of connection components are associated with a second volume; and
a ratio of the second volume to the first volume ranges from 20% to 99.9%;
wherein the thermoelectric solid material is associated with a thermoelectric figure of merit ZT larger than 0.1.

11. The thermoelectric solid material of claim 10, wherein the one or more voids are filled by one or more oxide materials.

12. The thermoelectric solid material of claim 10, wherein the one or more voids are filled by air.

13. The thermoelectric solid material of claim 10, wherein the one or more voids are one or more vacuums.

14. The thermoelectric solid material of claim 10, wherein:
the one or more first materials are thermoelectric;
the one or more voids are filled by one or more second materials; and
the one or more second materials are thermoelectric and different from the one or more first materials.

15. A thermoelectric solid material, the thermoelectric solid material comprising:
a plurality of silicon grains;
wherein:
each grain of the plurality of silicon grains is smaller than 250 nm in any dimension; and
each grain of the plurality of silicon grains corresponds to an aspect ratio equal to or larger than 10.

16. The thermoelectric solid material of claim 15 wherein the plurality of silicon grains occupy less than 90% of the total volume of the thermoelectric solid material.

17. The thermoelectric solid material of claim 15 wherein the thermoelectric solid material is associated with a thermoelectric figure of merit ZT larger than 0.1.

18. The thermoelectric solid material of claim 15 wherein each grain of the plurality of silicon grains is smaller than 250 nm in length, width, and height.

19. A thermoelectric solid material, the thermoelectric solid material comprising:
a plurality of nano structures;
wherein:
the thermoelectric solid material is associated with a Hausdorff dimension larger than zero and smaller than three; and
the thermoelectric solid material is associated with a thermoelectric figure of merit ZT larger than 0.1.

20. A method for making a thermoelectric solid material, the method comprising:
providing a plurality of nanowires, each nanowire of the plurality of nanowires being in contact with at least another nanowire of the plurality of nanowires; and
sintering the plurality of nanowires under a temperature higher than 25° C. or under a pressure higher than 760 torr to form the thermoelectric solid material.

21. The method of claim 20 wherein the sintering the plurality of nanowires includes forming, by diffusion, one or more chemical bonds between at least two nanowires of the plurality of nanowires.

22. The method of claim 20 wherein the sintering the plurality of nanowires is performed under the temperature higher than 25° C. and the pressure higher than 760 torr to form the thermoelectric solid material.

23. The method of claim 20 wherein the sintering the plurality of nanowires includes heating the plurality of nanowires by at least applying an electric current to the plurality of nanowires.

24. The method of claim 20 wherein the sintering the plurality of nanowires includes heating the plurality of nanowires by at least using a furnace.

25. The method of claim 20 wherein the providing a plurality of nanowires includes etching one or more parts of a silicon substrate to form the plurality of nanowires.

26. The method of claim 20, and further comprising providing a plurality of nanoparticles.

27. The method of claim 26 wherein the providing a plurality of nanowires and the providing a plurality of nanoparticles are performed by at least providing a mixture of the plurality of nanowires and the plurality of nanoparticles.

28. The method of claim 26, and further comprising doping the plurality of nanowires with the plurality of nanoparticles.

29. The method of claim 26, and further comprising hindering the sintering of the plurality of nanowires by at least the plurality of nanoparticles.

30. The method of claim 26, and further comprising assisting the sintering of the plurality of nanowires by at least the plurality of nanoparticles.

31. The method of claim 26 wherein the sintering the plurality of nanowires includes sintering the plurality of nanowires and the plurality of nanoparticles under the temperature higher than 25° C. or under the pressure higher than 760 torr to form the thermoelectric solid material.

32. The method of claim 26 wherein the sintering the plurality of nanowires includes performing one or more chemical reactions between the plurality of nanowires and the plurality of nanoparticles.

33. The method of claim 20 wherein:
the providing a plurality of nanowires includes providing the plurality of nanowires embedded within a matrix, the matrix including one or more fill materials located between the plurality of nanowires; and
the sintering the plurality of nanowires includes sintering the matrix including the plurality of nanowires and the one or more fill materials.

34. The method of claim 20 wherein:
the providing a plurality of nanowires includes providing one or more first nanowires of a first type and one or more second nanowires of a second type, the second type being different from the first type; and
the sintering the plurality of nanowires includes sintering the one or more first nanowires and the one or more second nanowires.

35. The method of claim 20 wherein:
the providing a plurality of nanowires includes providing a first layer of one or more first nanowires of a first type and a second layer; and
the sintering the plurality of nanowires includes sintering the first layer of the one or more first nanowires and the second layer.

36. The method of claim 35 wherein the second layer includes one or more second nanowires of a second type, the second type being different from the first type.

37. The method of claim 35 wherein:
the second layer includes one or more conductive materials; and
the sintering the first layer of the one or more first nanowires and the second layer includes forming the thermoelectric solid material including the sintered second layer of the one or more conductive materials.

38. A thermoelectric solid material made by a process comprising:
providing a plurality of nanowires, each nanowire of the plurality of nanowires being in contact with at least another nanowire of the plurality of nanowires; and
sintering the plurality of nanowires under a temperature higher than 25° C. or under a pressure higher than 760 torr to form the thermoelectric solid material.
